(19) United States
(12) Patent Application Publication
(10) Pub. No.: US 2018/0240797 A1
(43) Pub. Date: Aug. 23, 2018

(54) STACKED BODY

(71) Applicant: SONY CORPORATION, Tokyo (JP)

(72) Inventors: Takashi YOKOYAMA, Kanagawa (JP); Taku UMEBAYASHI, Kanagawa (JP)

(21) Appl. No.: 15/754,054

(22) PCT Filed: Aug. 9, 2016
(86) PCT No.: PCT/JP2016/073417

§ 371 Date: Feb. 21, 2018

(30) Foreign Application Priority Data
Sep. 1, 2015 (JP) 2015-172264
Mar. 4, 2016 (JP) 2016-042653

(51) Int. Cl. H01L 27/06; H01L 23/528; H01L 25/065; H01L 25/07; H01L 25/16; H01L 27/088; H01L 27/146; H01L 23/552; H01L 23/66

(52) U.S. Cl. CPC H01L 27/0688; H01L 23/528; H01L 25/0657; H01L 25/074; H01L 2223/6677; H01L 27/088; H01L 27/14634; H01L 23/552; H01L 23/66; H01L 25/167

(57) ABSTRACT

A stacked body according to an embodiment of the present technology includes: a plurality of transistors; a first substrate; and a second substrate that is stacked with the first substrate and is electrically coupled to the first substrate, in which a first transistor to be driven at a first driving voltage being a lowest voltage of the plurality of transistors is provided only in the first substrate of the first substrate and the second substrate to form a first circuit.

### TECHNICAL FIELD

The present technology relates to a stacked body including a plurality of circuits that includes a plurality of transistors having different driving voltages.

### BACKGROUND ART

In semiconductor integrated circuit devices, miniaturization and voltage reduction have been in progress according to a scaling rule of Moore's law to achieve an improvement in performance and reduction in electric power consumption. However, in devices of 14-nm generation or later generation, microfabrication technology exceeding a limit of lithography is used to form a diffusion layer, a gate, a contact, and a wiring via, which causes an increase in manufacturing cost.

In particular, to enable operation at a low voltage, a transistor structure shifts from an existing silicon (Si)planar structure to a three-dimensional structure typified by a fin-FET. Moreover, a road map of evolution of a semiconductor material is drawn from a Si material to germanium (Ge) and a compound base such as InGaAs, and further to a graphene structure. Accordingly, achieving a transistor having such a device structure has been a major issue.

Further, there has been a trend in recent years to mount a chip compatible with various communication bands in the semiconductor integrated circuit device such as a smartphone, which causes an issue that analog chips and logic chips for data processing in association with the chip are increased to increase a mounting area. In addition, there is an issue that a manufacturing procedure becomes extremely complicated, thereby further increasing manufacturing cost.

In contrast, for example, PTL 1 discloses a semiconductor device including circuits of which a circuit (high withstand voltage transistor-based circuit) including a high-voltage transistor and a circuit (low withstand voltage transistor-based circuit) including a transistor having a lower withstand voltage than the high withstand voltage transistor-based circuit are separately mounted in a first chip and a second chip, respectively.

### CITATION LIST

### Patent Literature

PTL 1: Japanese Unexamined Patent Application Publication No. 2011-159958

### SUMMARY OF THE INVENTION

However, in the semiconductor device described in PTL 1, the mounting area is reduced, but it is not said that complication of the manufacturing procedure and the increase in manufacturing cost are sufficiently resolved.

It is therefore desirable to provide a stacked body having a configuration suitable for easier manufacturing while reducing a mounting area.

A stacked body according to an embodiment of the present technology includes: a plurality of transistors; a first substrate; and a second substrate that is stacked with the first substrate and is electrically coupled to the first substrate, in which a first transistor to be driven at a first driving voltage being a lowest voltage of the plurality of transistors is provided only in the first substrate of the first substrate and the second substrate to form a first circuit.

In the stacked body according to the embodiment of the present technology, the first transistor to be driven at the first driving voltage being the lowest voltage of the plurality of transistors is formed only in one substrate (the first substrate) of the first substrate and the second substrate that are stacked and electrically coupled to each other. Accordingly, the plurality of transistors of different process technologies are divided into different substrates, which simplifies a manufacturing procedure.

According to the stacked body of the embodiment of the present technology, the first transistor to be driven at the first driving voltage being the lowest voltage of the plurality of transistors is formed only in the first substrate; therefore, the plurality of transistors of different process technologies are formed in different substrates, which simplifies the manufacturing procedure. In other words, it is possible to provide a stacked body having a configuration suitable for easier manufacturing while reducing a mounting area. It is to be noted that effects described here are non-limiting. Effects achieved by the technology may be one or more of effects described below.

### BRIEF DESCRIPTION OF THE DRAWINGS

FIG. 1 is a schematic view of a stacked body according to a first embodiment of the present disclosure.

FIG. 2A is a block diagram illustrating an example of a circuit configuration of a semiconductor device as a specific example of the stacked body illustrated in FIG. 1.

FIG. 2B is a block diagram illustrating another example of the circuit configuration of the semiconductor device as a specific example of the stacked body illustrated in FIG. 1.

FIG. 2C is a block diagram illustrating another example of the circuit configuration of the semiconductor device as a specific example of the stacked body illustrated in FIG. 1.

FIG. 3 is a cross-sectional view of an example of a configuration of the semiconductor device illustrated in FIG. 2.

FIG. 4 is a cross-sectional view that describes a structure of a transistor 20 illustrated in FIG. 3.

FIG. 5 is a cross-sectional view that describes a structure of the transistor 70 (fin-FET) illustrated in FIG. 3.

FIG. 6 is a cross-sectional view of another example (tri-gate) of the transistor 70 illustrated in FIG. 3.

FIG. 7 is a cross-sectional view of another example (nano-wire Tr) of the transistor 70 illustrated in FIG. 3.

FIG. 8 is a cross-sectional view of another example (FD-SOI) of the transistor 70 illustrated in FIG. 3.

FIG. 9 is a cross-sectional view of another example (T-FET) of the transistor 70 illustrated in FIG. 3.

FIG. 10A is a block diagram illustrating another example of the circuit configuration of the semiconductor device illustrated in FIG. 2.

FIG. 10B is a block diagram illustrating another example of the circuit configuration of the semiconductor device illustrated in FIG. 2.

FIG. 11 is a block diagram illustrating a circuit configuration of a typical semiconductor device.

FIG. 12 is a block diagram illustrating another example of a semiconductor device according to a second embodiment of the present disclosure.

FIG. 13 is a cross-sectional view illustrating an example of a semiconductor device according to a third embodiment of the present disclosure.

FIG. 14 is a cross-sectional view illustrating a configuration of a storage unit of a storage element illustrated in FIG. 13.

FIG. 15 is a cross-sectional view of an example of configurations of respective layers of the storage unit illustrated in FIG. 14.

FIG. 16 is a block diagram illustrating another example of a semiconductor device according to a fourth embodiment of the present disclosure.

FIG. 17A is a block diagram illustrating an example of a semiconductor device according to a fifth embodiment of the present disclosure.

FIG. 17B is a block diagram illustrating another example of the semiconductor device according to the fifth embodiment of the present disclosure.

FIG. 18 is a cross-sectional view of an example of a configuration of the semiconductor device illustrated in FIG. 17A.

FIG. 19A is a block diagram illustrating another example of the semiconductor device according to the fifth embodiment of the present disclosure.

FIG. 19B is a block diagram illustrating another example of the semiconductor device according to the fifth embodiment of the present disclosure.

FIG. 20 is a cross-sectional view of a configuration of a semiconductor device according to a modification example 1 of the present disclosure.

FIG. 21A is a block diagram illustrating an example of a semiconductor device according to a sixth embodiment of the present disclosure.

FIG. 21B is a cross-sectional view of an example of a configuration of the semiconductor device illustrated in FIG. 21A.

FIG. 22 is a cross-sectional view of another example of a configuration of a capacitor illustrated in FIG. 21B.

FIG. 23 is a plan view of an example of an antenna illustrated in FIG. 21B.

FIG. 24A is a plan view of an example of a shield shape illustrated in FIG. 21B.

FIG. 24B is a plan view of another example of the shield shape illustrated in FIG. 21B.

FIG. 24C is a plan view of another example of the shield shape illustrated in FIG. 21B.

FIG. 24D is a plan view of another example of the shield shape illustrated in FIG. 21B.

FIG. 25 is a flow chart illustrating a procedure of manufacturing the semi conductor device illustrated in FIG. 21B.

FIG. 26A is a schematic view that describes the procedure of manufacturing the semiconductor device illustrated in FIG. 25.

FIG. 26B is a schematic view of a process following FIG. 26A.

FIG. 27A is a schematic view of a process following FIG. 26B.

FIG. 27B is a schematic view of a process following FIG. 27A.

FIG. 28A is a block diagram illustrating an example of a semiconductor device according to a modification example 2 of the present disclosure.

FIG. 28B is a block diagram illustrating another example of the semiconductor device according to the modification example 2 of the present disclosure.

FIG. 29 is a cross-sectional view of an example of a configuration of the semiconductor device illustrated in FIGS. 28A and 28B.

FIG. 30 is a cross-sectional view that describes a configuration of a transistor 620 illustrated in FIG. 29.

FIG. 31A is a block diagram illustrating an example of a semiconductor device according to a modification example 3 of the present disclosure.

FIG. 31B is a block diagram illustrating another example of the semiconductor device according to the modification example 3 of the present disclosure.

FIG. 32 is a cross-sectional view of an example of a configuration of the semiconductor device illustrated in FIG. 31.

### MODES FOR CARRYING OUT THE INVENTION

In the following, some embodiments of the present disclosure are described in detail with reference to the drawings. It is to be noted that description is given in the following order.
1. First Embodiment (a semiconductor device including a logic circuit and an analog circuit for communication in a first substrate)
2. Second Embodiment (a semiconductor device including an analog circuit that configures a sensor in a second substrate)
3. Third Embodiment (a semiconductor device including a storage element in the second substrate)
4. Fourth Embodiment (a semiconductor device including an interface physical circuit in the second substrate and a digital controller circuit in the first substrate)
5. Fifth Embodiment (a semiconductor device having a three-layer configuration)
6. Modification Example 1 (a semiconductor device in which the first substrate and the second substrate are electrically coupled to each other through a TSV)
7. Sixth Embodiment (a semiconductor device including a functional element on a back surface of the second substrate)
8. Modification Example 2 (a semiconductor device having a three-layer configuration)
9. Modification Example 3 (an example in which the first substrate including the logic circuit is stacked on the second substrate including the analog circuit)

### 1. First Embodiment

### (1-1. Basic Configuration)

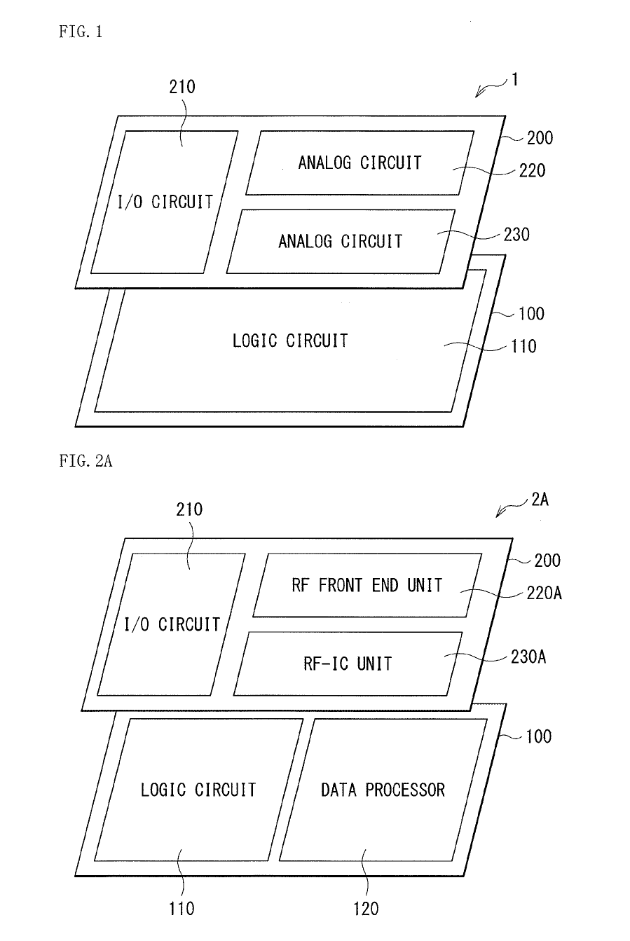

FIG. 1 illustrates a schematic configuration of a stacked body (a stacked body 1) according to a first embodiment of the present disclosure. The stacked body 1 configures a semiconductor device, and includes a plurality of substrates (herein, a first substrate 100 and a second substrate 200) that are stacked and are electrically coupled to one another. The stacked body 1 includes a plurality of transistors having different driving voltages, which configure an analog circuit (for example, an I/O circuit 210) and a digital circuit (for example, a logic circuit 110). The stacked body 1 according to the present embodiment has a configuration in which a transistor to be driven at a lowest voltage of the plurality of transistors having different voltages is formed only in one substrate (herein, the first substrate 100).

The transistor to be driven at the lowest voltage of the plurality of transistors provided in the stacked body 1 is provided in the first substrate 100 as described above, and a circuit including this transistor having the lowest driving voltage is mounted in the first substrate 100. This circuit is, for example, a logic circuit (the logic circuit 110), and the logic circuit 110 may include, in addition to the transistor having the lowest driving voltage, a transistor to be driven at a relatively low voltage, i.e., a transistor other than a transistor to be driven at a highest voltage of the plurality of transistors included in the stacked body 1. The transistor to be driven at a relatively low voltage is, for example, a transistor of 20-nm generation or lower generation, and more preferably a transistor of 14-nm generation or later generation. Herein, “nm generation” originally indicates a minimum size of a portion where processing of a gate length, etc. is difficult, but does not indicate the size of a specific portion at present. The size is reduced by a factor of about 0.7 with succeeding generations.

Examples of the transistor provided in the first substrate 100 include a transistor using a high dielectric constant film/metal gate (high-K/metal gate) technology and a transistor having a three-dimensional structure, as described in detail later. Examples of the transistor having the three-dimensional structure include a fin field effect transistor (fin-FET), a tri-gate transistor, a nano-wire transistor, an FD-SOI transistor, a T-FET, etc. It is possible for these transistors to use, in addition to Si, an inorganic semiconductor such as Ge or a compound semiconductor such as a group H1-V semiconductor and a group II-VI semiconductor, for example. Specific examples thereof include InGaAs, InGaSb, SiGe, GaAsSb, InAs, InSb, InGanZnO (IGZO), MoS₂, WS₂, boron nitride, and silicane germanene. In addition, a graphene transistor using graphene is adopted.

Of the plurality of transistors included in the stacked body 1, a transistor to be driven at the highest voltage, specifically, a planar transistor typically using a Si substrate is provided in the second substrate 200, and a circuit including the transistor having the highest driving voltage is mounted. This circuit is, for example, an analog circuit, and examples thereof include the input/output (I/O) circuit 210 and various kinds of analog circuits 220 and 230. Of the plurality of transistors included in the stacked body 1, a transistor other than the transistor to be driven at the lowest voltage may be provided, in addition to the transistor having the highest driving voltage, in the I/O circuit 210 and the analog circuits 220 and 230. Specifically, the transistor mounted in the second substrate 200 is preferably a transistor of 20-nm generation or higher generation, and more preferably a transistor of earlier generation than 20-nm generation.

### (1-2. Configuration of Semiconductor Device)

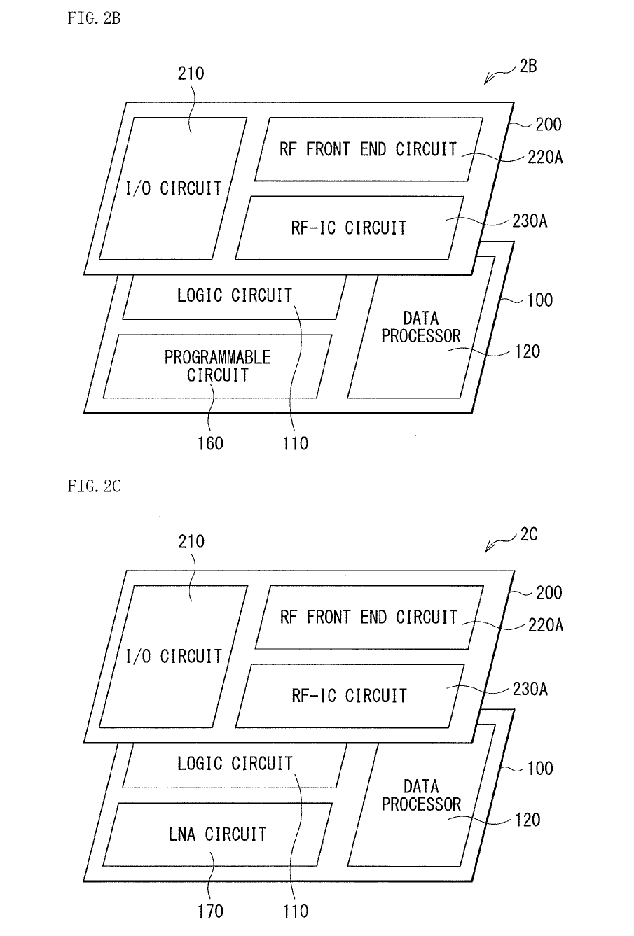

FIG. 2A is a block diagram illustrating a configuration of a semiconductor device (a semiconductor device 2A) as the first embodiment of the present disclosure. The semiconductor device 2A includes a platform for communication applicable to various frequency bands from a close distance to a far distance. Of the first substrate 100 and the second substrate 200 that are electrically coupled to each other, the first substrate 100 includes the logic circuit 110 and a data processor 120 for baseband, and the second substrate 200 includes, as analog circuits, for example, an RF front end unit 220A including a transmit-receive switch and a power amplifier and an RF-IC unit 230A including a low noise amplifier and a transmit-receive mixer, in addition to the I/O circuit 210. In addition, the second substrate 200 may include a circuit configuring a signal processor such as an ADC and a DAC and a switch processor that performs switching of respective frequency bands.

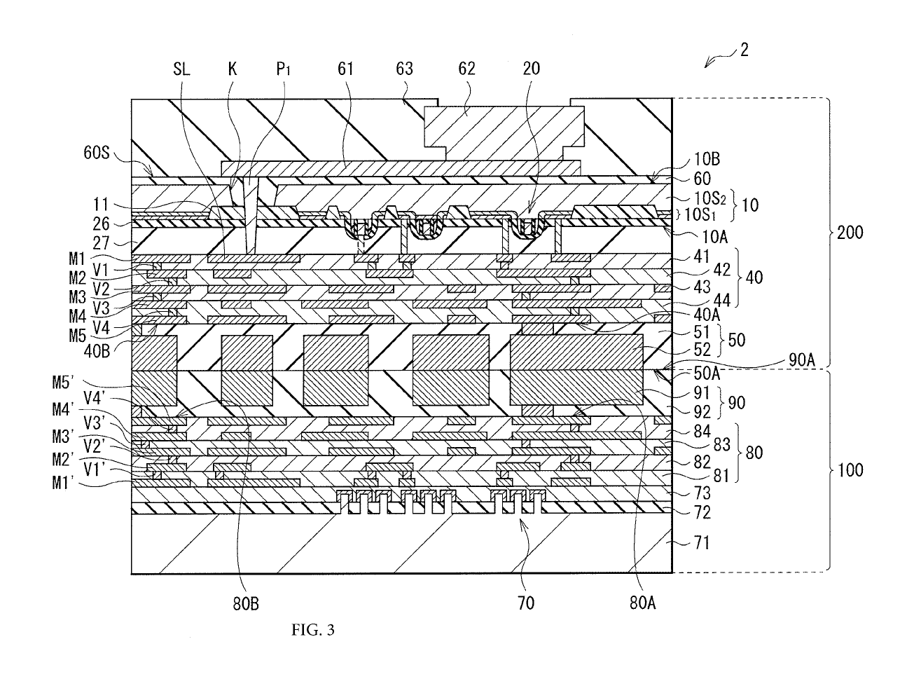

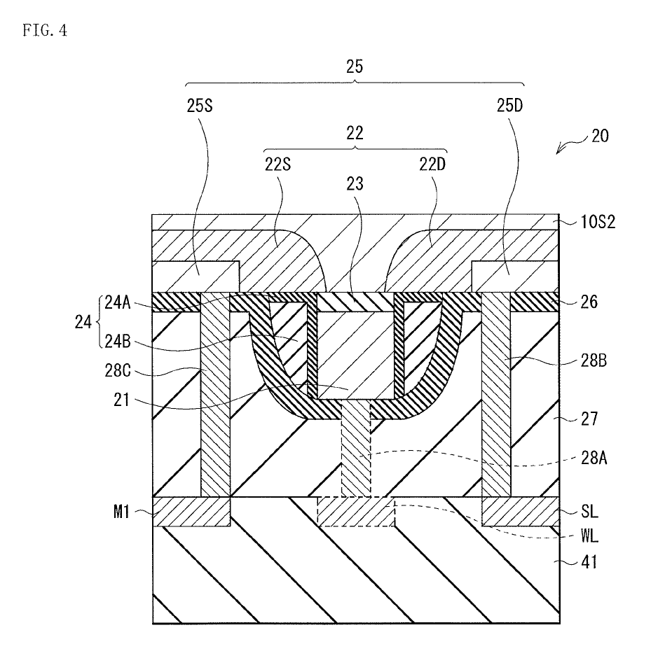

FIG. 3 illustrates a cross-sectional configuration of the semiconductor device 2A illustrated in FIG. 2A, and herein illustrates an example in which a transistor having a Si-planar structure (a Si-planar transistor 20) as a transistor configuring the I/O circuit 210, the RF front end unit 220A, and the RF-IC unit 230A is provided in the second substrate 200 and a transistor 70 having a fin-FET structure as a transistor configuring the logic circuit 110 and the data processor 120 is provided in the first substrate 100.

The second substrate 200 includes, for example, a multilayer wiring formation unit 40 and a surface wiring formation unit 50 that are stacked in this order on a principal surface (a front surface) of a semiconductor substrate 10. The Si-planar transistor 20 is provided in proximity to the principal surface 10A of the semiconductor substrate 10, and a conductive layer 61 and a pad (a metal film 62) are provided on a back surface 10B of the semiconductor substrate 10 with an insulating layer 60 in between. It is to be noted that in FIG. 2A, a case where three transistors 20 are provided is exemplified; however, the number of transistors 20 provided in the semiconductor substrate 10 is not particularly limited, and may be one, or two or more. Moreover, a transistor other than the Si-planar transistor may be provided.

The semiconductor substrate 10 includes an element separation layer 11 formed by, for example, STI (shallow trench isolation). The element separation layer 11 is, for example, an insulating film including a silicon oxide film (SiO₃₂), and one surface thereof is exposed to the principal surface 10A of the semiconductor substrate 10.

The semiconductor substrate 10 has a stacked configuration including a first semiconductor layer 1051 (hereinafter referred to as semiconductor layer 10S1) and a second semiconductor layer 10S2 (hereinafter referred to as semiconductor layer 10S2). In the semiconductor layer 10S1, for example, a channel region and a pair of diffusion layers (to be described later) that configure a portion of the transistor 20 are formed in single-crystal silicon. In contrast, the semiconductor layer 10S2 differs in polarity from the semiconductor layer 10S1, and is formed to cover both the semiconductor layer 10S1 and the element separation layer 11. The semiconductor layer 10S2 includes, for example, single-crystal silicon.

A surface of the semiconductor layer 10S2, that is, the back surface 10B of the semiconductor substrate 10 is covered with the insulating layer 60. The semiconductor layer 10S2 has an aperture 10K, and the aperture 10K is filled with the insulating layer 60. Moreover, for example, a contact plug P₁ that extends to penetrate through a portion where the insulating layer 60 and the element separation layer 11 are coupled to each other is provided in a portion of the aperture 10K. The contact plug P₁ includes, for example, a material mainly containing a low-resistance metal such as Cu (copper), W (tungsten) or aluminum (Al). Moreover, a barrier metal layer including a simple substance of Ti (titanium) or Ta (tantalum), an alloy thereof, or the like may be provided around these low-resistance metals. Surroundings of the contact plug P₁ are covered with the insulating layer 60, and the contact plug P₁ is electrically separated from the semiconductor substrate 10 (a semiconductor layer 10S).

The transistor 20 is a Si-planar transistor, and includes, for example, a gate electrode 21 and a pair of diffusion layers 22 (22S and 22D) configuring a source region and a drain region, as illustrated in FIG. 4.

The gate electrode 21 is provided on the principal surface 10A of the semiconductor substrate 10. Note that a gate insulating film 23 including a silicon oxide film, etc. is provided between the gate electrode 21 and the semiconductor substrate 10. It is to be noted that a thickness of the gate insulating film 23 is thicker than a thickness of a transistor having a three-dimensional structure such as a fin-FET to be described later. For example, a side wall 24 including a laminated film that includes a silicon oxide film 24A and a silicon nitride film 24B is provided on a side surface of the gate electrode 21.

The pair of diffusion layers 22 include, for example, silicon into which an impurity is diffused, and configure the semiconductor layer 10S1. Specifically, the pair of diffusion layer 22 includes a diffusion layer 22S corresponding to a source region and a diffusion layer 22D corresponding to a drain region, which are provided with the channel region in between. The channel region faces the gate electrode 21 in the semiconductor layer 10S1. For example, silicide regions 25 (25S and 25D) including a metal silicide such as NiSi (nickel silicide) or CoSi (cobalt silicide) are provided in respective portions of the diffusion layers 22 (22S and 22D). The silicide regions 25 reduce contact resistance between connection units 28A and 28C to be described later and the diffusion layers 22. Whereas a surface of each of the silicide regions 25 is exposed to the principal surface 10A of the semiconductor substrate 10, a surface opposite the surface is covered with the semiconductor layer 10S2. Moreover, a thickness of the diffusion layer 22 and a thickness of the silicide region 25 each are thinner than a thickness of the element separation layer 11.

A metal film M1 is embedded in the interlayer insulating film 27. Moreover, connection units 28A to 28D are provided to penetrate through the interlayer insulating films 26 and 27. The silicide region 25D serving as the drain region of the diffusion layer 22D and the silicide region 25S serving as the source region of the diffusion layer 22S are respectively coupled, through the connection unit 28B and the connection unit 28C, to the metal film M1 of a wiring line 40A to be described later. The contact plug P₁ penetrates through the interlayer insulating films 26 and 27, and a bottom end thereof is in contact with, for example, a selection line SL. Thus, the contact plug P₁ extends to penetrate through all of the insulating layer 60, the element separation layer 11, the interlayer insulating film 26, and the interlayer insulating film 27. The contact plug P₁ has, for example, a truncated pyramid shape or a truncated cone shape, and herein, areas occupied by these shapes increase from the principal surface 10A to the back surface 10B (that is, from a bottom end to a top end).

In the multilayer wiring formation unit 40, for example, an interlayer insulating film 41, an interlayer insulating film 42, an interlayer insulating film 43, and an interlayer insulating film 44 are stacked in order from a side close to the transistor 20, and are provided with wiring lines 40A and 40B. The wiring lines 40A and 40B each have a configuration in which the metal film M1, a metal film M2, a metal film M3, a metal film M4, and a metal film MS are stacked. Herein, the metal film M1, the metal film M2, the metal film M3, the metal film M4, and the metal film MS are respectively embedded in the interlayer insulating film 27, the interlayer insulating film 41, the interlayer insulating film 42, the interlayer insulating film 43, and the interlayer insulating film 44. Moreover, the metal film M1 and the metal film M2 are coupled to each other through a via V1 that penetrates through the interlayer insulating film 41. Likewise, the metal film M2 and the metal film M3 are coupled to each other through a via V2 that penetrates through the interlayer insulating film 42. The metal film M3 and the metal film M4 are coupled to each other through a via V3 that penetrates through the interlayer insulating film 43. The metal film M4 and the metal film MS are coupled to each other through a via V4 that penetrates through the interlayer insulating film 44. As described above, the wiring line 40A is coupled to the diffusion layers 22 serving as the drain region and the source region through the connection unit 28B and the connection unit 28C, respectively, that are in contact with the metal film M1. It is to be noted that the configuration of the multilayer wiring formation unit 40 illustrated in FIG. 2A is a non-limiting example.

The surface wiring formation unit 50 that is surface-bonded to the first substrate 100 is provided on the multilayer wiring formation unit 40. In the surface wiring formation unit 50, a metal film 52 including, for example, copper (Cu) is embedded in a surface of an insulating film 51, and the metal film 52 is coupled to the metal film M5 of the multilayer wiring formation unit 40 through a via V5 that penetrates through the insulating film 51.

The insulating layer 60 is provided to cover the semiconductor substrate 10, as described above. The insulating layer 60 has, for example, a multilayer configuration in which, for example, a high-K (high dielectric constant) film that is formable at a low temperature, a SiO₂ film, and a material having a lower dielectric constant (low-K) than SiO₂ are stacked. Examples of the high-K (high dielectric constant) film that is formable at a low temperature include Hf oxide, Al₂O₃, Ru (ruthenium) oxide, Ta oxide, an oxide including one of Al, Ru, Ta, and Hf, and Si, a nitride including one of Al, Ru, Ta, and Hf, and Si, an oxynitride including one of Al, Ru, Ta, and Hf, and Si. The conductive layer 61 is provided on a surface 60S (that is, a surface opposite to the semiconductor substrate 10) of the insulating layer 60. The conductive layer 61 is in contact with the top end of the contact plug P₁, and the opposite surface of the conductive layer 61 is in contact with a pad for external coupling (with the metal film 62).

It is to be noted that a fine back surface contact may be formed on the back surface 10B of the semiconductor substrate 10. Providing the fine back surface contact in an uppermost layer of the semiconductor device 2A makes it possible to configure an external coupling electrode from anywhere, and to achieve multiple pin connection. Moreover, this makes it easy to form a bump, etc., and advantageously acts on an IR drop in wiring. Further, a protective circuit or a protective diode that protects the second substrate 200 may be provided on the back surface 10B of the semiconductor substrate 10.

The transistor 70 having a fin-FET structure as a transistor configuring the logic circuit 110 and the data processor 120 is provided in the first substrate 100.

The transistor 70 having a fin-FET structure includes, for example, a fin 71A, a gate insulating film 73 and a gate electrode 74. The fin 71A includes Si, and has a source region 71S and a drain region 71D.

The fin 71A has a flat shape, and a plurality of fins 71A are provided to stand on a semiconductor substrate 71 including, for example, Si. The plurality of fins 71A each extend, for example, in an X direction and are aligned in a Y-axis direction. An insulating film 72 including, for example, Si0₂ is provided on the semiconductor substrate 71. Portions of the fins 71A are embedded in the insulating film 72. Side surfaces and top surfaces of the fins 71A exposed from the insulating film 72 are covered with the gate insulating film 73 including, for example, HfSiO, HfSiON, TaO, TaON, or the like. The gate electrode 74 extends in a Z direction intersecting with an extending direction (the X direction) of the fins 71A to straddle the fins 71A. A channel region 71C is formed in a portion intersecting with the gate electrode 74 of each of the fins 71A and the source region 71S and the drain region 71D are formed at both ends with the channel region 71C in between. It is to be noted that a cross-sectional configuration of the transistor 70 illustrated in FIG. 3 illustrates a cross-section taken along a line I-I in FIG. 4.

In the multilayer wiring formation unit 80, for example, an interlayer insulating film 81, an interlayer insulating film 82, an interlayer insulating film 83, and an interlayer insulating film 84 are stacked in order from a side close to the transistor 70, and are provided with wiring lines 80A and 80B. The wiring lines 80A and 80B each have a configuration in which a metal film M1′, a metal film M2′, a metal film M3′, a metal film M4′, and a metal film M5′ are stacked. Herein, the metal film M1′, the metal film M2′, the metal film M3′, and the metal film M4′ and the metal film MS′ are respectively embedded in the interlayer insulating film 81, the interlayer insulating film 82, the interlayer insulating film 83, and the interlayer insulating film 84. Moreover, the metal film M1′ and the metal film M2′ are coupled to each other through a via V1′ that penetrates through the interlayer insulating film 41. Likewise, the metal film M2° and the metal film M3′ are coupled to each other through a via V2′ that penetrates through the interlayer insulating film 82. The metal film M3′ and the metal film M4′ are coupled to each other through a via V3′ that penetrates through the interlayer insulating film 83. The metal film M4′ and the metal film MS° are coupled to each other through a via V4′ that penetrates through the interlayer insulating film 84. It is to be noted that the configuration of the multilayer wiring formation unit 80 illustrated in FIG. 2A is a non-limiting example.

A surface wiring formation unit 90 that is surface-bonded to the second substrate 200 is provided on the multilayer wiring formation unit 80. In the surface wiring formation unit 90, a metal film 92 including, for example, copper (Cu) is embedded in a surface of an insulating film 91, and the metal film 92 is coupled to the metal film MS' of a multilayer wiring formation unit 980 through a via VS' that penetrates through the insulating film 91.

The first substrate 100 and the second substrate 200 are electrically coupled to each other by bonding (surface-vonding) a plurality of metal films 52 and 92 respectively embedded in the surface wiring formation unit 50 and the surface wiring formation unit 90 in the above-described manner It is to be noted that the metal films 52 and 92 may use, for example, aluminum (Al), gold (Au), etc. in addition to Cu, and is preferably formed using the same material as that of the wiring lines 40A, 40B, 80A, and 80B. Thus, bonding the first substrate 100 and the second substrate 200 to each other by surface-bonding allows for fine pitch bonding, and improves flexibility in routing of wiring lines. Moreover, this makes it possible to dispose more transistors in a narrower region, thereby achieving high integration.

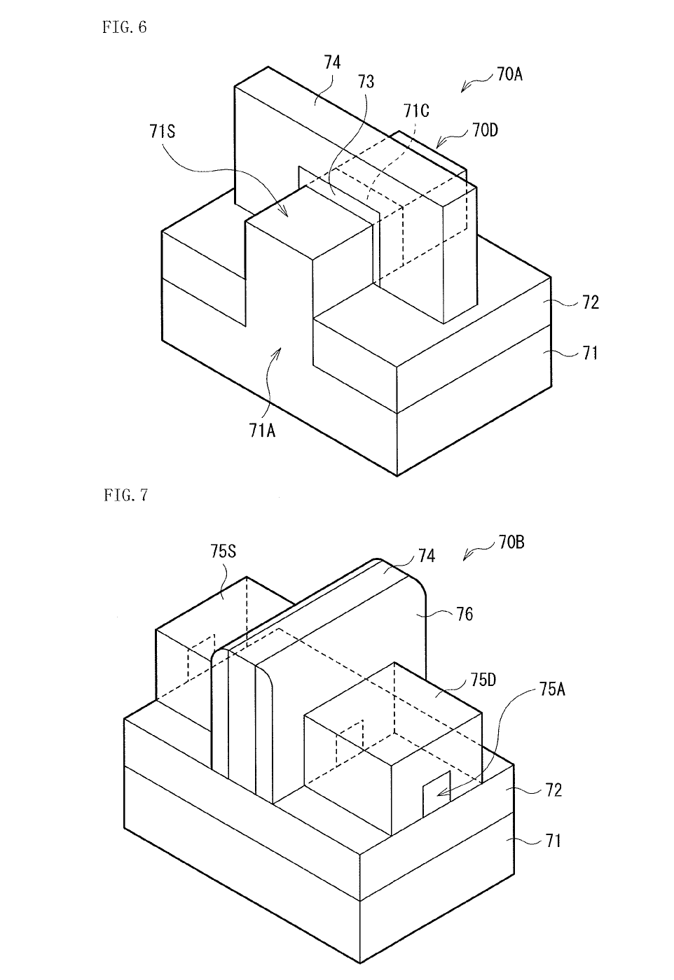

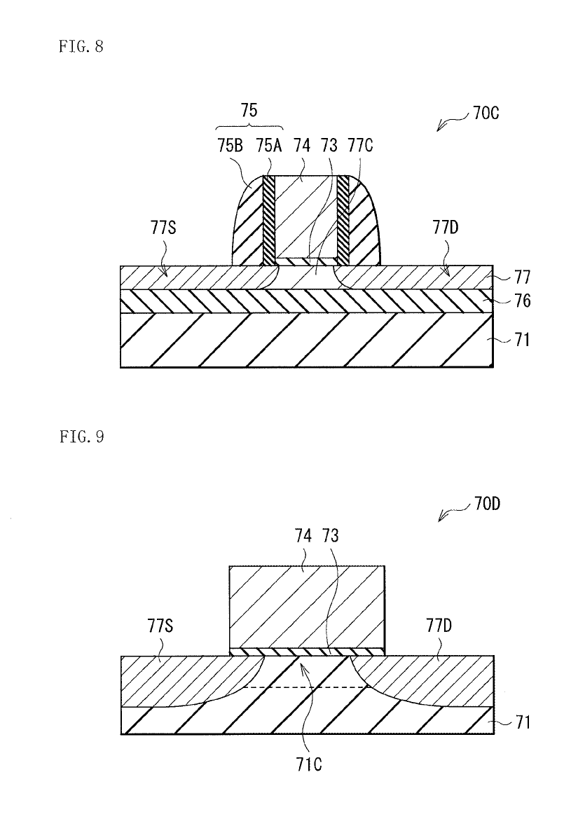

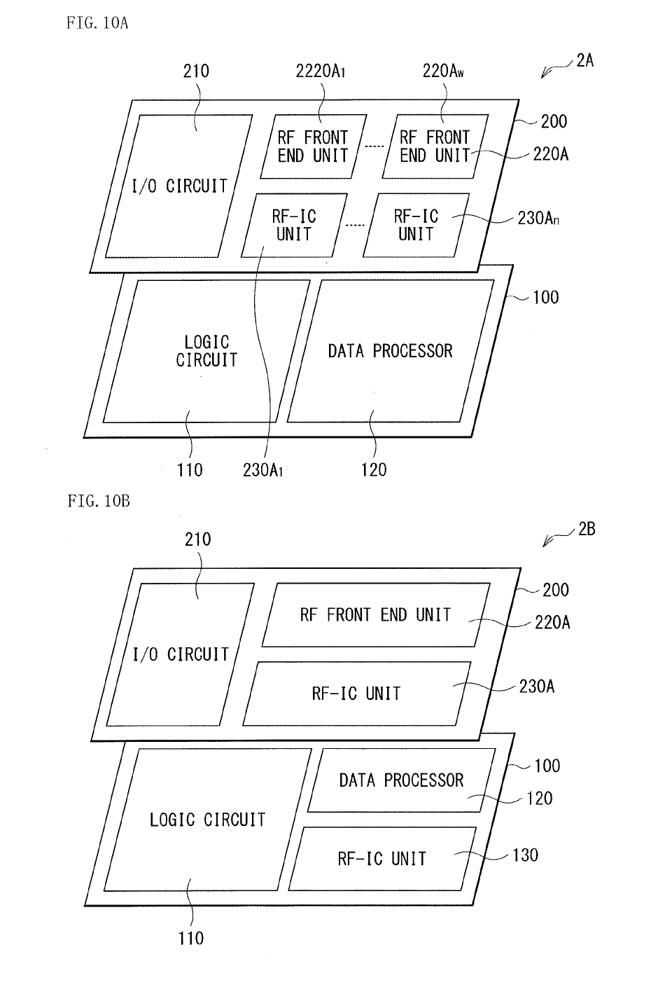

It is to be noted that the transistor 70 herein is a transistor having a fin-FET structure; however, the transistor 70 is not limited thereto, and may be any fully-depleted transistor other than the fin-FET. Moreover, as the fully-depleted transistor, a tri-gate transistor 70A (FIG. 6), a nano-wire transistor 70B (FIG. 7), and a FD-SOI transistor 70C (FIG. 8) are adopted. In addition, for example, a transistor using a high dielectric constant film/metal gate (high-K/metal gate) teleology, and a tunnel-FET (T-FET) 70D (FIG. 9) may be adopted.

The transistor using the high dielectric constant film/metal gate technology is the same planar transistor as the transistor 20, but uses a high dielectric material for a gate insulating film and a low-resistance metal for a gate electrode. Examples of the high dielectric material include hafnium oxide. The transistor having such a structure makes it possible to reduce a gate leakage current while thinning the gate insulating film.

FIG. 6 schematically illustrates a structure of the tri-gate transistor 70A. The tri-gate transistor 70A includes the fin 71A that extends in one direction and includes Si and the gate electrode 74 substantially orthogonal to the fin 71A as with the transistor 70 having a fin-FET structure illustrated in FIG. 4, and the gate insulating film 73 is provided between the gate electrode 74 and the fin 71A as with the fin-FET. Both left and right surfaces and a top surface of the fin 71A are surrounded by the gate electrode 74, and each of the surfaces serves as a gate as with the fin-FET. In the fin 71A, the channel region 71C is formed in a portion intersecting with the gate electrode 74, and the source region 71S and the drain region 71D are formed at both ends with the channel region 71C in between. It is to be noted that the tri-gate transistor 70A differs from the fin-FET in that in addition to the side surfaces of the fin 71A, the top surface of the fin 71A also serves as a channel

FIG. 7 schematically illustrates a structure of the nano-wire transistor 70B. The nano-wire transistor 70B is a transistor having a three-dimensional structure as with the transistor 70 and the tri-gate transistor 70A. In the nano-wire transistor 70B, a silicon nanowire 75A through which a current flows is covered with the gate electrode 74, and a source region 75S and a drain region 75D are formed on both sides of the gate electrode 74 with a gate side wall 76 in between. In the nano-wire transistor 70B, left and right side surfaces and a top surface of the silicon nanowire 75A are covered with the gate electrode 74, which suppresses occurrence of an off-current. Moreover, reducing a diameter of the silicon nanowire 75A suppresses occurrence of a leakage current.

FIG. 8 illustrates a cross-sectional configuration of a fully-depleted silicon-on-insulator (FD-SOI) transistor 70C. The FD-SOI transistor 70C has a planar transistor structure as with the transistor 20. In the FD-SOI transistor 70C, an insulating layer 79 called an embedded oxide film is provided between the semiconductor substrate 71 and a silicide layer 77 configuring a channel region 77C, a source region 77S, and a drain region 77D. In the FD-SOI transistor 70C, a thickness of the silicide layer 77 is extremely thin, e.g., 10 nm or less, and the silicide layer 77 does not need channel doping; therefore, it is possible for the FD-SOI transistor 70C to become fully depleted.

FIG. 9 illustrates a cross-sectional configuration of a tunnel field effect transistor (T-FET) 70D. The T-FET 70D has a planar transistor structure as with the transistor 20, and is a transistor that performs on-off control with use of an electron band-to-band tunneling phenomenon. In the T-FET 70D, one of the source region 77S and the drain region 77D is formed including a p-type conductive semiconductor, and the other is formed including an n-type semiconductor.

It is to be noted that FIG. 2A illustrates an example in which the first substrate 100 includes the logic circuit 110 and the data processor 120, and the second substrate 200 includes one FR front end unit 220A and one RF-IC unit 230A in addition to the I/O circuit 210, but the configuration is not limited to the example. For example, in order to comply with communication standards at various frequencies, for example, the second substrate 200 may include a plurality of kinds of RF front end units 220A1 to 220An and a plurality of kinds of RF-IC units 230A1 to 230An, as illustrated in FIG. 10A. Moreover, for example, in order to enable change or automatization of operations of a semiconductor device, software, a system, etc. on an as-needed basis, for example, a circuit (a programmable circuit) that is programmable may be formed in the first substrate 100, as with a semiconductor device 2B illustrated in FIG. 2B. For example, an FPGA (field-programmable gate array) and a CPU (central processing unit) are mounted in the programmable circuit.

Moreover, in a case where a circuit mounted in the RF front end unit 220A and the RF-IC unit 230A includes, for example, a transistor having a low driving voltage such as a fin field effect transistor, for example, the circuit portion (for example, a LNA circuit 170) may be provided in the first substrate 100, as with the semiconductor device 2C illustrated in FIG. 2C. For example, a low noise amplifier (LNA) circuit included in the RF-IC unit 230A uses a transistor having a three-dimensional structure such as the transistor 70, which improves characteristics (for example, cutoff frequency and maximum oscillation frequency). It is to be noted that, of circuits mounted in the RF-IC unit 230A, a circuit that is allowed to be provided in the first substrate 100 is not limited to the foregoing LNA circuit 170. A circuit configured using a transistor having a three-dimensional structure such as the transistor 70 is preferably provided in the first substrate 100, even if the circuit is a circuit generally referred to as an analog circuit such as the RF-IC unit 230A.

Moreover, in a case where transistors having different driving voltages are included in a circuit configured as an analog circuit, a transistor to be driven at a relatively low voltage in the analog circuit may be provided in the first substrate 100. For example, in a case where the RF-IC unit 230A includes transistors to be driven at mutually different voltage values, a circuit portion including a transistor to be driven at a low voltage of the transistors configuring the RF-IC unit 230A may be provided in the first substrate 100 (an RF-IC unit 130), as illustrated in FIG. 10B.

### (1-3. Workings and Effects)

As described above, in semiconductor integrated circuit devices, miniaturization and voltage reduction have been in progress according to the scaling rule of Moore's law, and microfabrication exceeding a limit of lithography heretofore used has been in demand recently. In particular, manufacturing of a transistor having a three-dimensional structure typified by a fin-FET, etc. needs finer microfabrication technology than that of existing Si-planar transistors, which causes an increase in manufacturing cost.

Moreover, in recent years, a chip compatible with various communication bands is mounted in the semiconductor integrated circuit device such as a smartphone. In a typical semiconductor integrated circuit device (a semiconductor device 2A000), for example, chips (I/O circuits 1110A to 1110D) compatible with various communication bands, and analog chips (analog circuits 1130 and 1140) and a logic chip (a logic circuit 1150) for data processing in association with the chips are mixed in one substrate (a substrate 1100), as illustrated in FIG. 11. Accordingly, a mounting area tends to increase. Moreover, a transistor having a high driving voltage (for example, 3.3 V to 1.8 V) is included in these I/O circuits 1110A to 1110D and these analog circuits 1130 and 1140. The transistor having a high driving voltage differs in process technology from a transistor drivable at a low voltage. In general, a planar transistor is classified into a transistor having a high driving voltage, and, for example, leading-edge transistors having a three-dimensional structure are classified into a transistor drivable at a low voltage. It is difficult for the fin-FET that is one of the leading-edge transistors having a three-dimensional structure to achieve desired characteristics by simple change such as changing a thickness of a gate insulating film to form the planar transistor, and it is necessary to add a large number of processes. Further, some of the leading-edge transistors use a novel material such as graphene, which causes a fundamental issue that the leading-edge transistor is not allowed to be formed including the same material as that of the planar transistor. Hence, it is extremely difficult to form the transistor having a high driving voltage and the transistor drivable at a low voltage at the same time, and in a case where these transistors are manufactured at the same time, a manufacturing procedure becomes extremely complicated, thereby further increasing the manufacturing cost.

As a method of achieving reduction in mounting area and manufacturing cost and simplification of the manufacturing procedure, the method as described above is considered. In the method, of a plurality of transistors mounted in a semiconductor device, a high withstand voltage transistor-based circuit and a low withstand voltage transistor-based circuit including a transistor having a lower withstand voltage than the high withstand voltage transistor-based circuit are separately mounted in a first chip and a second chip, respectively. However, in this method, the mounting area is reduced, but it is difficult to sufficiently resolve complication of the manufacturing procedure and the increase in manufacturing cost.

In contrast, in the present embodiment, of the plurality of transistors included in the semiconductor device 2A (and the semiconductor device 2B), the transistor drivable at a low voltage and the transistor having a high driving voltage are provided in different substrates. Specifically, the transistor 70 to be driven at the lowest voltage is formed only in the first substrate 100, and the transistor 20 having a high driving voltage and having, for example, a Si-planar structure is provided in the second substrate 200. Accordingly, the transistor (herein, the transistor 70) formed with use of a leading-edge process and the transistor (the transistor 20) formed with use of an existing manufacturing process are formed in different substrates, and while a formation region of the transistor using the leading-edge process is reduced, the manufacturing procedure is simplified.

As described above, in the semiconductor device 2A (and the semiconductor device 2) according to the present embodiment, of the plurality of transistors mounted in the semiconductor device 2A, the transistor 70 to be driven at the lowest voltage and the transistor 20 having a higher driving voltage than the transistor 70 and having, for example, a Si-planar structure are provided in different substrates. This makes it possible to reduce the mounting area and to manufacture the transistor using the leading-edge process and the transistor using existing manufacturing process in different manufacturing lines. In other words, it is possible to simplify a procedure of manufacturing a circuit substrate including the transistors and to reduce manufacturing cost. Moreover, the manufacturing procedure is simplified, which makes it possible to improve manufacturing yields.

Further, in the present embodiment, the platform for communication applicable to various frequency bands from a close distance to a far distance is mounted such that the data processor 120 for baseband including a transistor drivable at a low voltage is mounted in the first substrate 100, and the RF front end unit 220A including, for example, the transmit-receive switch and the power amplifier, the RF-IC unit 230A including the low noise amplifier and the transmit-receive mixer, and the like are mounted in the second substrate 200. Examples of short-range communication standards include NFC, 1.2-GHz or 1.5-GHz GPS, 2.4-GHz or 5-GHz Wi-Fi, 2.45 G W-LAN (bluetooth (registered trademark)), millimeter waves at 60 GHz or 90 GHz or more. 2G-3G, LTE, 5G, etc. Long-range communication standards include Zigbee, bluetooth, WiMAX, etc. Thus, it is possible to reduce the mounting area.

In addition, in a case where the analog circuit includes transistors having different driving voltages, a circuit portion including a transistor to be driven at a low voltage of the transistors having different driving voltages may be provided in the first substrate 100. This makes it possible to further reduce the mounting area of the analog circuit that is prone to increase in general.

Next, description is given of second to fifth embodiments and modification examples. It is to be noted that components corresponding to the components of the semiconductor device 2A according to the foregoing first embodiment are denoted by same reference numerals.

### 2. Second. Embodiment

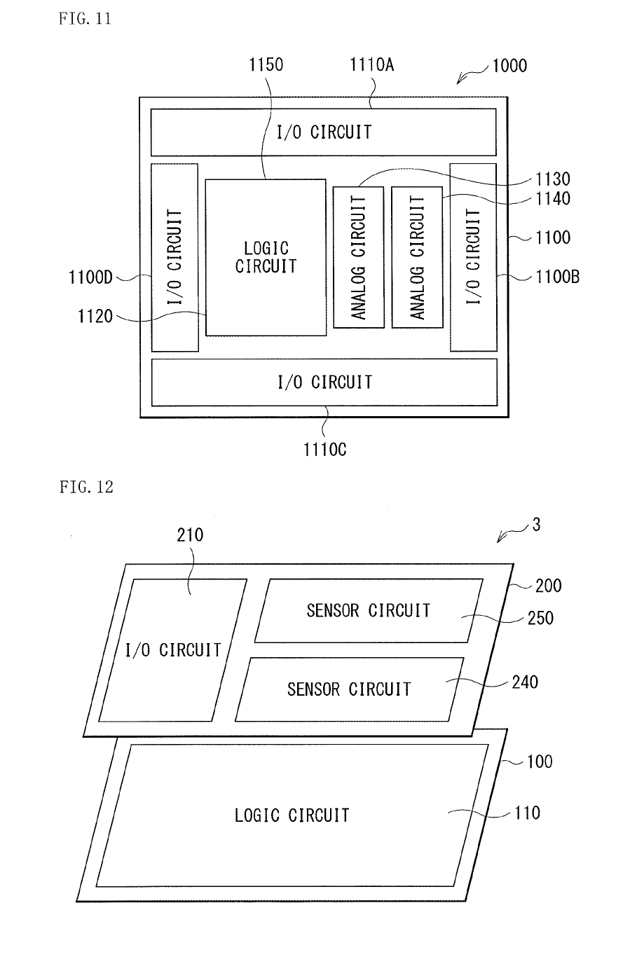

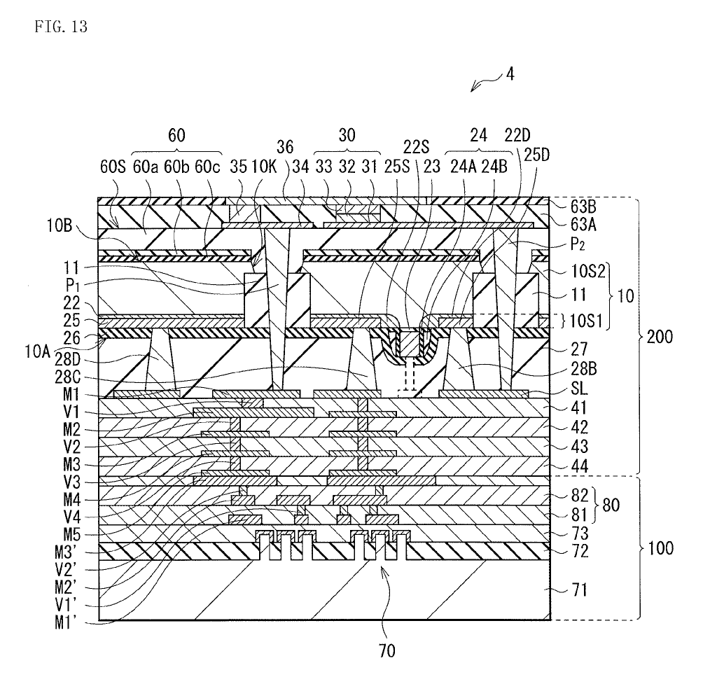

FIG. 12 illustrates a schematic configuration of a semiconductor device 3 as the second embodiment of the present disclosure. In the semiconductor device 2A according to the present embodiment, in addition to the I/O circuit 210 as an analog circuit, analog circuits (a sensor circuit 240 and a sensor circuit 250) having various sensor functions such as an image sensor, a temperature sensor, a gravity sensor, and a position sensor are mounted in the second substrate 200.

It is to be noted that in a case where the analog circuit having a sensor function includes transistors having different driving voltages, a circuit portion including a transistor to be driven at a low voltage of the transistors having different driving voltages may be separately provided in the first substrate 100, as with the foregoing first embodiment. This makes it possible to further reduce the mounting area of the analog circuit that is prone to increase in general.

### 3. Third Embodiment

FIG. 13 illustrates a cross-sectional configuration of a semiconductor device 4 as the third embodiment of the present disclosure. In the semiconductor device 4 according to the present embodiment, in addition to the I/O circuit 210 that is an analog circuit, an analog circuit having a memory function may be mounted in the second substrate 200. In the semiconductor device 4, a storage element 30 is provided on the surface of the semiconductor layer 1052, i.e., the back surface 10B of the semiconductor substrate 10 with the insulating layer 60 including three layers (60a, 60b, and 60c) in between. An example of an insulating layer 60a is a high-K (high dielectric constant) film that is formable at a low temperature, i.e., Hf oxide, A1₂O₃, Ru (ruthenium) oxide, Ta oxide, an oxide including one of Al, Ru, Ta, and Hf, and Si, a nitride including one of Al, Ru, Ta, and Hf, and Si, or an oxynitride including one of Al, Ru, Ta, and Hf, and Si. Insulating layers 60b and 60c include, for example, SiO₂. Alternatively, the insulating layer 60c desirably includes a material (low-K) having a lower dielectric constant than SiO₂. Conductive layers 31 and 34 are provided on a surface 63S (that is, a surface opposite to the semiconductor substrate 10) of an insulating layer 63. The conductive layers 31 and 34 are respectively in contact with the top ends of contact plugs P₁ and P₂. Here, a magnetoresistance element (magnetic tunnel junction; MTJ) as the storage element 30 is described as an example.

In the storage element 30, for example, a conductive layer 31 serving as a lower electrode, a storage unit 32, and a conductive layer 33 serving as an upper electrode (and also serving a bit line BL) are stacked in order. The conductive layer 31 is coupled to the silicide region 25 through the contact plug P₁, the selection line SL, and the connection unit 28B.

A back-surface interlayer film (an insulating layer 63A) is provided around the storage unit 32 and the conductive layers 31, 33, and 34. As a material of the insulating layer 63A, SiO₂, a low-K (low dielectric constant) film, or the like is adopted. Moreover, a pillar-shaped conductive layer 35 is provided on the conductive layer 34, and is also embedded in the insulating layer 63A. Further, the conductive layer 33 and the conductive layer 35 are electrically coupled to each other through the conductive layer 36 covering the conductive layers 33 and 35 together. Surroundings of the conductive layer 36 is embedded in the insulating layer 63B.

The storage unit 32 in the storage element 30 is preferably a spin transfer magnetization switching storage element (STT-MTJ; Spin Transfer Torque-Magnetic Tunnel Junctions) in which orientation of magnetization of a storage layer to be described later is reversed by spin transfer to store information. The STT-MTJ is allowed to perform writing and reading at high speed; therefore, the STT-MTJ is a promising non-volatile memory in place of a volatile memory.

The conductive layer 31 and the conductive layer 33 each include, for example, a metal layer including Cu, Ti, W, Ru, etc. The conductive layer 31 and the conductive layer 33 each preferably include a metal other than a constituent material of a base layer 32A or a cap layer 32E to be described later, that is, mainly include Cu, Al, and W. Moreover, it is possible for the conductive layer 31 and the conductive layer 33 to include any of Ti, TiN (titanium nitride), Ta, TaN (tantalum nitride), W, Cu, and Al, and a stacked configuration thereof

FIG. 14 illustrates an example of a configuration of the storage unit 32. The storage unit 32 has, for example, a configuration including the base layer 32A, a magnetization fixed layer 32B, an insulating layer 32C, and the storage layer 32D in order from side close to the conductive layer 31. In other words, the storage element 30 has a bottom-pin configuration including the magnetization fixed layer 32B, the insulating layer 32C, and the storage layer 32D in order from a bottom to a top in a stacking direction. Orientation of magnetization M32D of the storage layer 32D having uniaxial anisotropy is changed to store information. Information “0” or “1” is defined by a relative angle (parallel or antiparallel) between magnetization M32D of the storage layer 32D and magnetization M32B of the magnetization fixed layer 32B.

The base layer 32A and the cap layer 32E each include any of a metal film including Ta, Ru, etc. and a laminated film thereof.

The magnetization fixed layer 32B is a reference layer serving as a reference of storage information (magnetization direction) of the storage layer 32D, and includes a ferromagnetic substance having a magnetic moment in which a direction of magnetization M32B is fixed to a direction perpendicular to a film surface. The magnetization fixed layer 32B includes, for example, Co—Fe—B.

It is not desirable to change the direction of the magnetization M32B of the magnetization fixed layer 32B depending on writing or reading; however, it is not necessary to fix the direction to a specific direction, because it is only necessary for the direction of the magnetization M32B of the magnetization fixed layer 32B to move less easily than the direction of the magnetization M32D of the storage layer 32D. For example, it is only necessary for the magnetization fixed layer 32B to have larger coercivity, a larger magnetic film thickness, or a larger damping constant than the storage layer 32D. In order to fix the direction of the magnetization M32B, for example, it is only necessary to provide an antiferromagnetic substance such as PtMn and IrMn in contact with the magnetization fixed layer 32B. Alternatively, a magnetic substance in contact with such an antiferromagnetic substance may be magnetically coupled to the magnetization fixed layer 32B with a nonmagnetic substance such as Ru in between to indirectly fix the direction of the magnetization M32B.

The insulating layer 32C is an intermediate layer serving as a tunnel barrier layer (a tunnel insulating layer), and includes, for example, aluminum oxide or magnesium oxide (MgO). In particular, the insulating layer 32C preferably includes magnesium oxide, which makes it possible to increase a magnetoresistance change ratio (MR ratio), and to improve spin transfer efficiency, thereby reducing current density for reversal of the direction of the magnetization M32D of the storage layer 32D.

The storage layer 32D includes a ferromagnetic substance having a magnetic moment that freely changes the direction of magnetization M32D to the direction perpendicular to the film surface. The storage layer 32D includes, for example, Co—Fe—B.

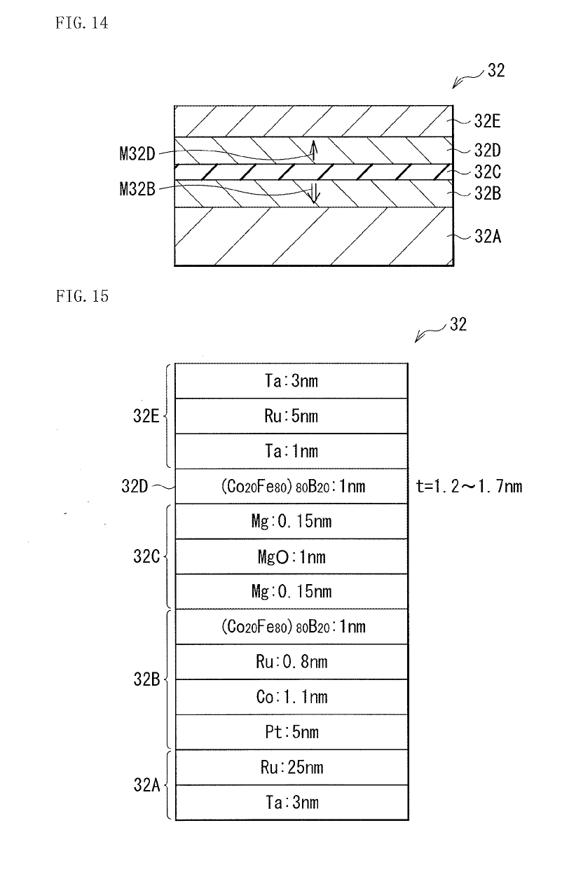

FIG. 15 illustrates an example of configurations of respective layers of the storage unit 32 in more detail. The base layer 32A has, for example, a configuration in which a 3-nm thick Ta layer and a 25-nm thick Ru film are stacked in order from a side close to a first electrode (the conductive layer 31). The magnetization fixed layer 32B has, for example, a configuration in which a 5-nm thick Pt layer, a 1.1-nm thick Co layer, a 0.8-nm thick Ru layer, and a 1-nm thick (Co₂₀Fe₈₀)₈₀B₂₀ layer are stacked in order from the side close to the first electrode (the conductive layer 31). The insulating layer 32C has, for example, a configuration in which a 0.15-nm thick Mg layer, a 1-nm thick MgO layer, and a 0.15-nm Mg layer are stacked in order from the side close to the first electrode (the conductive layer 31). The storage layer 32D has, for example, a thickness t of 1.2 nm to 1.7 nm, and includes a (Co₂₀,Fe₈₀)₈₀B₂₀ layer. The cap layer 32E has, for example, a configuration in which a 1-nm thick Ta layer, a 5-nm thick Ru layer, and a 3-nm thick Ta layer in order from the side close to the first electrode (the conductive layer 31).

It is to be noted that in the present embodiment, MTJ is described as an example of the storage element 30; however, the storage element 30 may be any other non-volatile element or a volatile element. Examples of the non-volatile element include a resistance change element such as a ReRAM and a FLASH in addition to the MTJ, and examples of the volatile element include a DRAM, an SPRAM, etc.

Moreover, in a case where the analog circuit having a memory function includes transistors having different driving voltages, as with the foregoing first embodiment, a circuit portion including a transistor to be driven at a low voltage of the transistors having different driving voltages may be provided in the first substrate 100. Alternatively, in a case where all transistors forming the analog circuit having a memory function are transistors to be driven at a low voltage, the storage element 30 itself may be provided in the first substrate 100. This makes it possible to further reduce the mounting area of the analog circuit that is prone to increase in general. It is to be noted that an example in which the storage element 30 is provided on the back surface 10B of the semiconductor substrate 10 is indicated herein; however, the present embodiment is not limited thereto, and the storage element 30 may be formed inside the multilayer wiring formation unit 40.

### 4. Fourth Embodiment

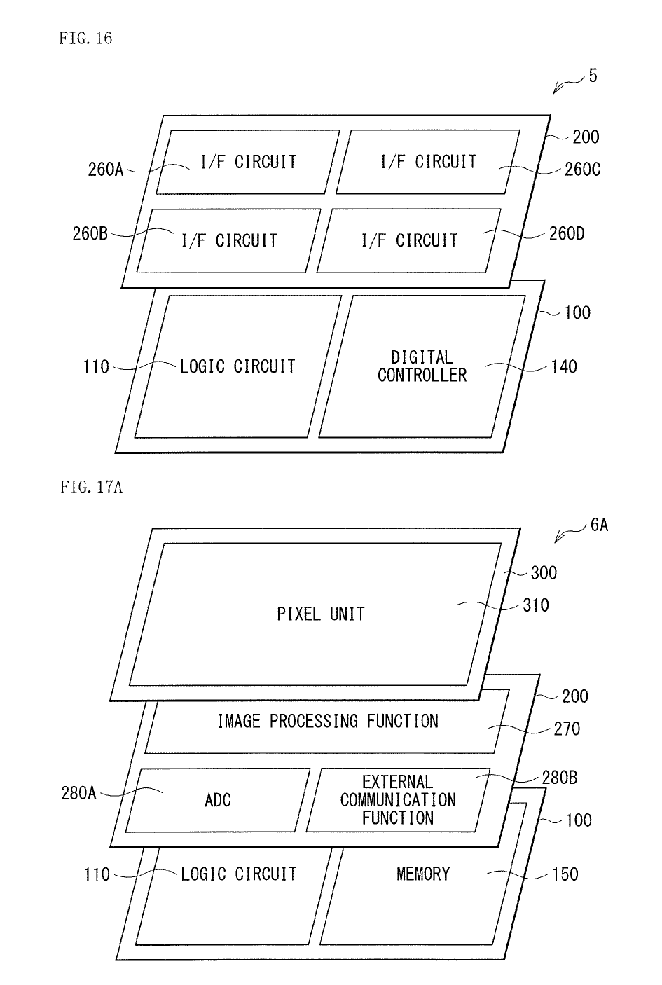

FIG. 16 illustrates a schematic configuration of the semiconductor device 4 as a fifth embodiment of the present disclosure. In the semiconductor device 5 according to the present embodiment, various interfaces are mounted as analog circuits in the second substrate 200. Examples of interface standards include an MIPI (Mobile Industry Processor Interface), a USB (Universal Serial Bus), an HDMI (High-Definition Multimedia Interface (registered trademark)), a LVDS (Low voltage differential signaling), Thunderbolt, etc. The various interfaces are formed in one substrate in such a manner, and the substrate serves as an interface platform chip, which makes it possible to reduce an area of the chip. Moreover, mounting an interface platform chip for various standards as with the present embodiment makes it possible to provide a semiconductor device that is compatible with all interface standards.

It is to be noted that in a case where a circuit including transistors having different driving voltages is mixed in one platform as with the first embodiment, a circuit including a transistor having a low driving voltage is preferably mounted in the first substrate 100, as described in the foregoing first embodiment. For example, the MIPI includes a PHY unit and a digital controller as analog circuits, and the digital controller includes a transistor drivable at a low voltage in general. Accordingly, the digital controller and the PHY unit are preferably separately mounted in the first substrate 100 and the second substrate 200, respectively. Moreover, a circuit block including a transistor drivable at a low voltage in the PHY unit may be provided in the first substrate 100.

### 5. Fifth Embodiment

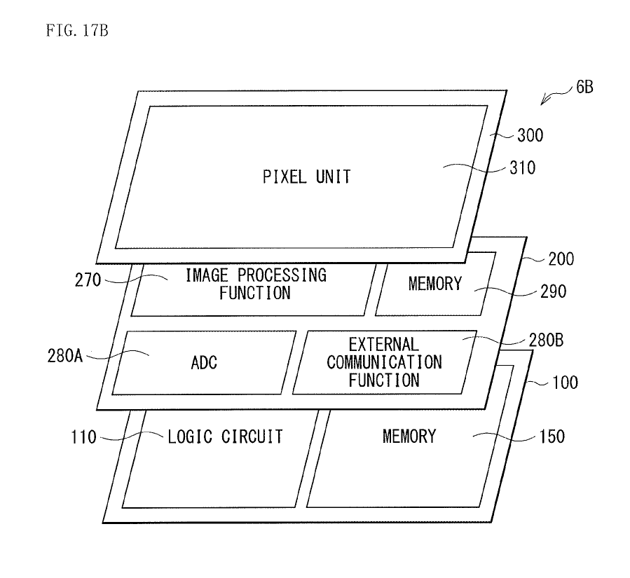

FIGS. 17A and 17B each illustrate an example of a schematic configuration of a semiconductor device 6 as a fifth embodiment of the present disclosure. The semiconductor device 6 is, for example, a stacked imaging device, and has a configuration in which the first substrate 100 including the logic circuit 110 and a second substrate including various analog circuits, and a third substrate including a pixel unit 310 are stacked.

In addition to a logic circuit formed including a transistor that is drivable at a low voltage such as a control circuit, a memory 150 formed including a transistor that is drivable at a low voltage, for example, including the non-volatile element mentioned in the third embodiment is mounted in the first substrate 100, as with the foregoing embodiments. For example, a circuit 270, an ADC (analog-digital converter) circuit 280A, a circuit 280B, etc. may be mounted in the second substrate 200. The circuit 270 has an image processing function. The ADC circuit 280A converts an analog signal outputted from a unit pixel provided in the pixel unit into a digital signal and outputs the digital signal. The circuit 280B has, for example, an external communication function such as Wi-Fi. It is to be noted that it is not necessary to mount the non-volatile element in the first substrate 100, and a portion of the non-volatile element may be provided as a memory 290 in the second substrate 200, as illustrated in FIG. 17B. A third substrate 300 includes the pixel unit 310, and in the pixel unit 310, unit pixels are two-dimensionally arranged, and includes, for example, a transfer transistor, a reset transistor, an amplifier transistor, etc. The transfer transistor transfers an electric charge obtained by a photoelectric converter and photoelectric conversion to an FD (floating diffusion) unit. The reset transistor resets a potential of the FD unit. The amplifier transistor outputs a signal corresponding to the potential of the FD unit. Thus, the transistors having a high driving voltage may be separately formed in the second substrate 200 and the third substrate 300.

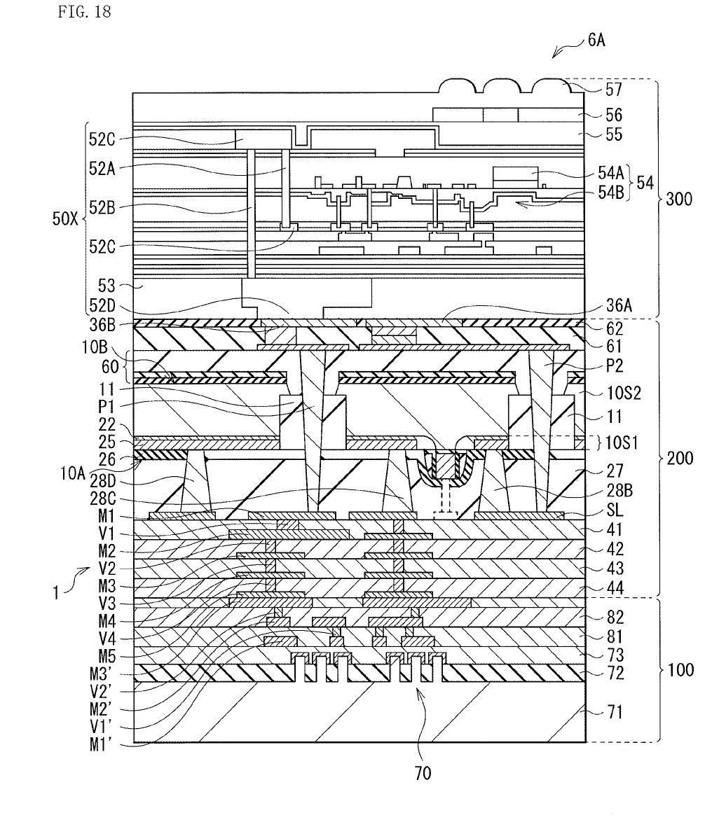

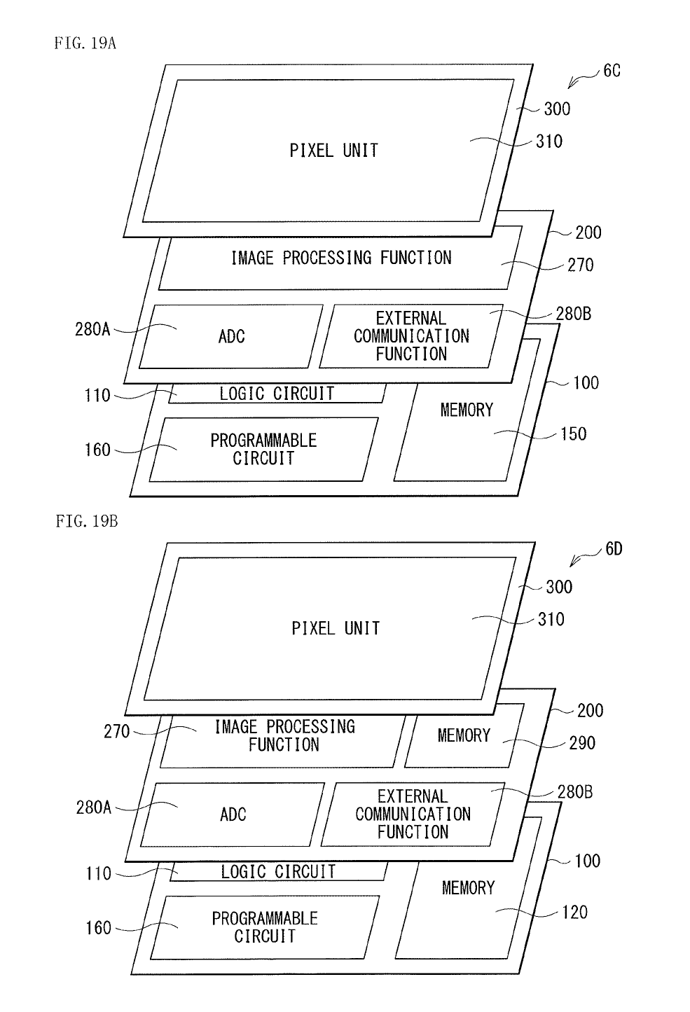

FIG. 18 illustrates an example of a cross-sectional configuration of the semiconductor device 6 (an imaging device) illustrated in FIG. 17A, for example. The semiconductor device 6 includes a back side illumination type photoelectric converter 50X stacked on the second substrate 200. In the present embodiment, an uppermost layer of the second substrate 200 includes conductive layers 36A and 36B including, for example, Cu, and the third substrate 300 including the photoelectric converter 50X includes a conductive layer 52D including, for example, Cu in an lowermost layer thereof. The second substrate 200 and the third substrate 300, i.e., the conductive layer 36B and the conductive layer 52D are coupled to each other through connection units 52A and 52B that penetrate a part or the entirety of the photoelectric converter 50X in a thickness direction, the conductive layer 52C located in an uppermost portion of the photoelectric converter 50X, and the conductive layer 53 located in a lowermost layer of the photoelectric converter 50X. For example, a planarization film 55, a color filter layer 56, and a microlens 57 are provided in this order on the semiconductor substrate 54 in which the photoelectric converter 50X is embedded.

In the stacked imaging device, an analog circuit region tends to increase. Moreover, capacity of a memory temporarily holding image data tends to increase, which causes a demand for securing a mounting area. In contrast, in the present embodiment, the logic circuit 110 including a transistor drivable at a low voltage and an analog circuit (the analog circuit 370 having an image processing function and the ADC circuit 280) including a transistor having a high driving voltage are separately mounted in different substrates (the first substrate 100 and the second substrate 200), and the memory 130 including a transistor drivable at a low voltage as with the logic circuit is mounted in the first substrate 100, which makes it possible to reduce the mounting area of the analog circuit and to secure mounting areas of other circuits having various functions. It is to be noted that FIG. 18 illustrates an example in which the third substrate 300 and the second substrate 200 are coupled to each other through a through-Si electrode (a through-silicon via; TSV) such as the connection units 52A and 52B; however, the present embodiment is not limited thereto. For example, the third substrate 300 and the second substrate 200 may be coupled to each other by surface-bonding between metal wiring lines, as with coupling between the first substrate 100 and the second substrate 200.

It is to be noted that in the semiconductor device 6 of the present disclosure, like semiconductor devices 6C and 6D illustrated in FIGS. 19A and 19B, a programmable circuit may be formed in the first substrate 100, as with the semiconductor device 2B according to the foregoing first embodiment. This makes it possible to change and automate an operation of the imaging device on an as-needed basis.

### 6. Modification Example 1

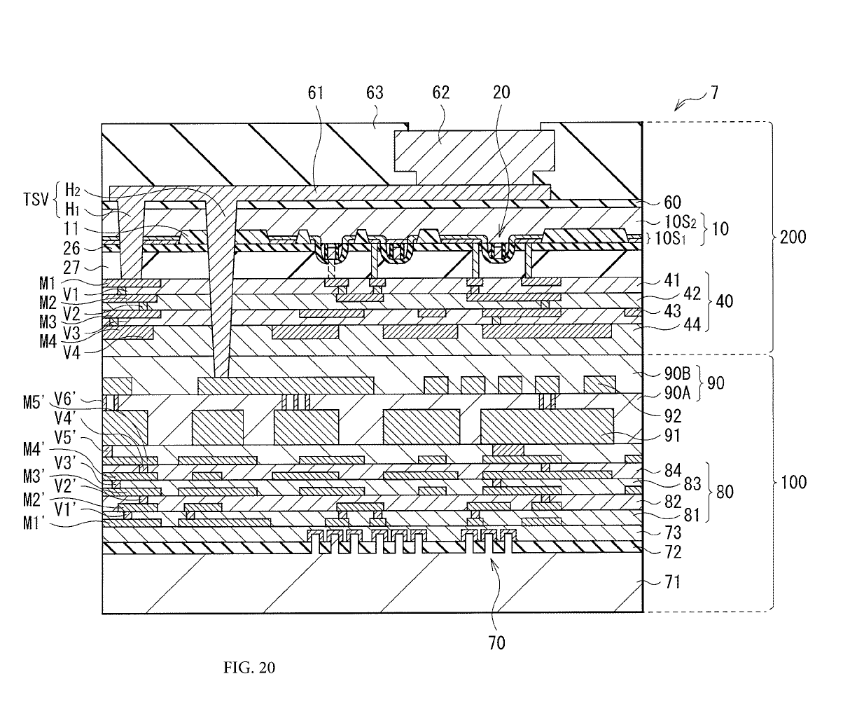

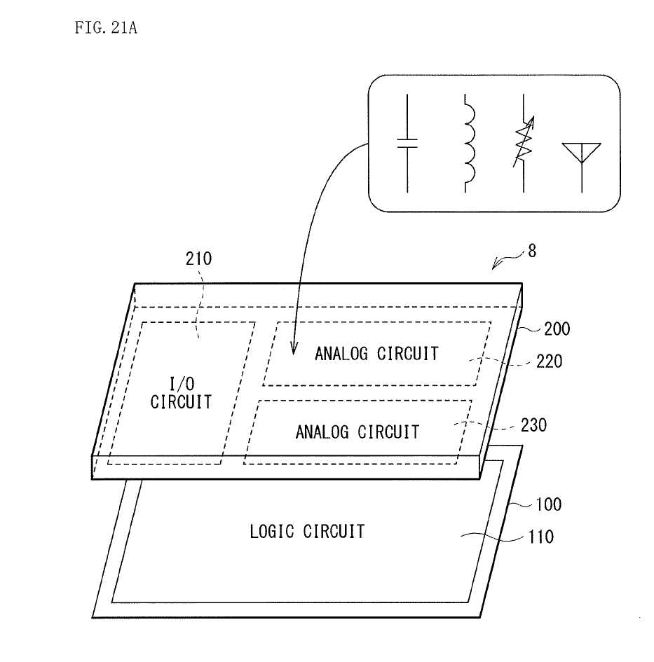

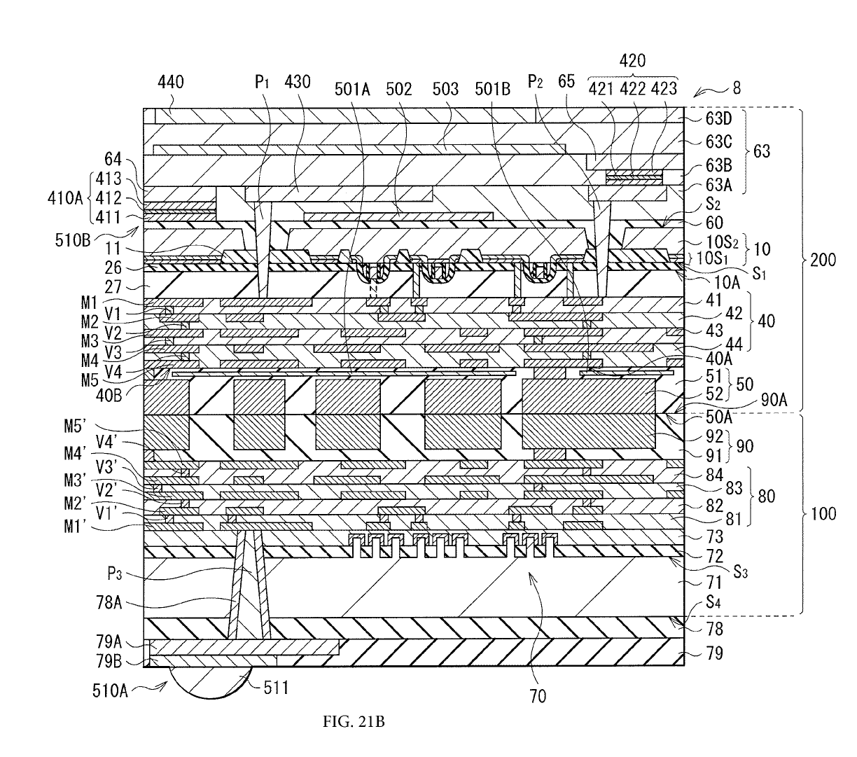

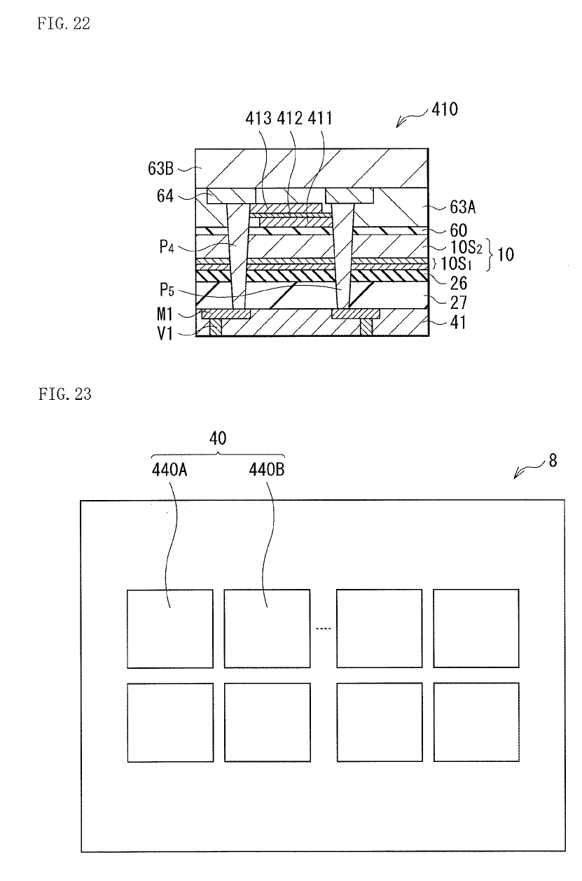

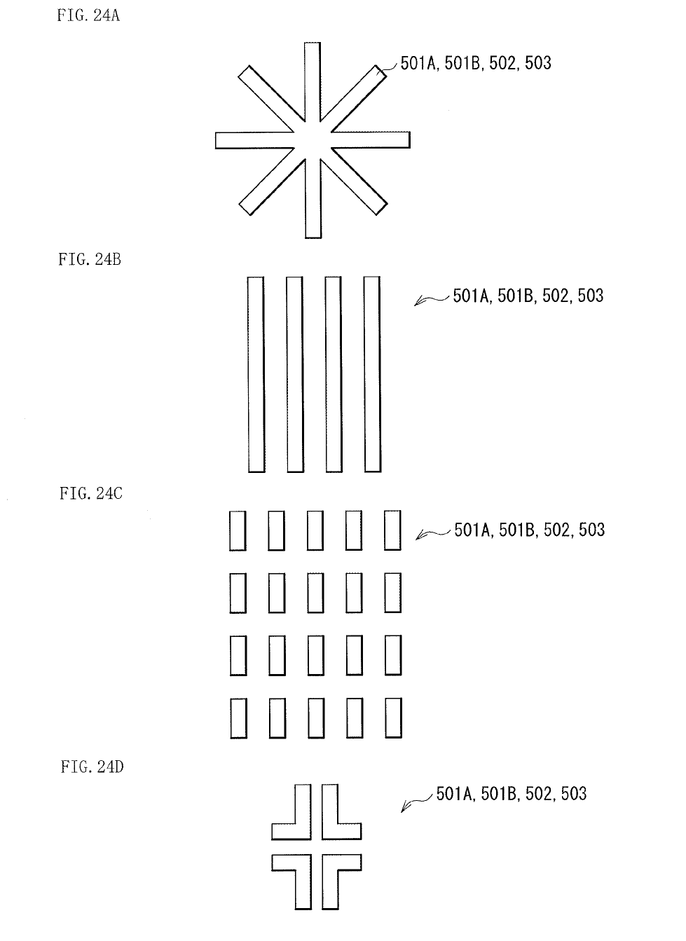

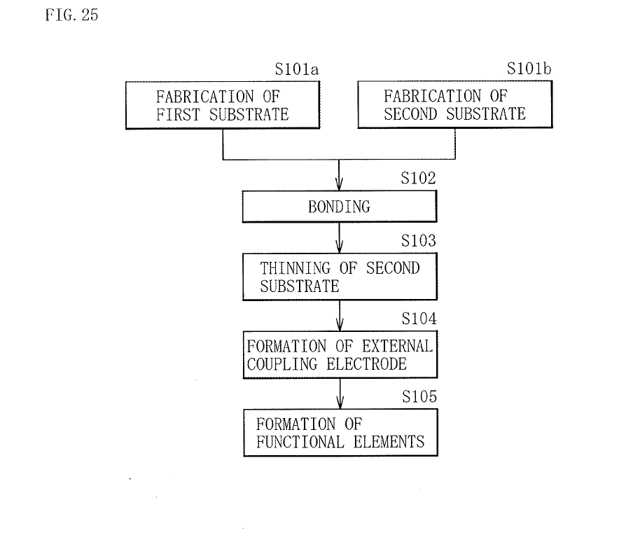

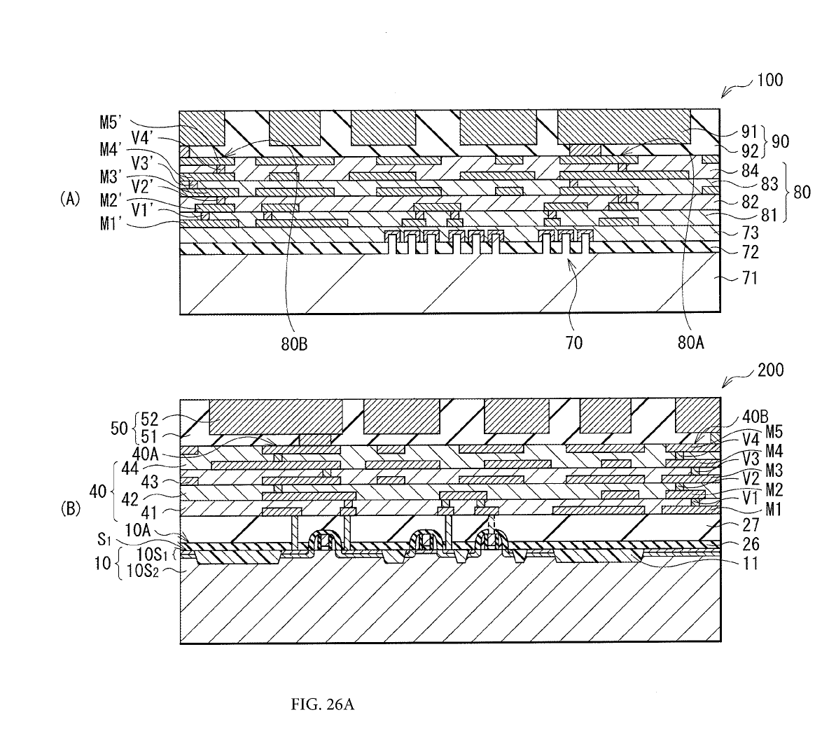

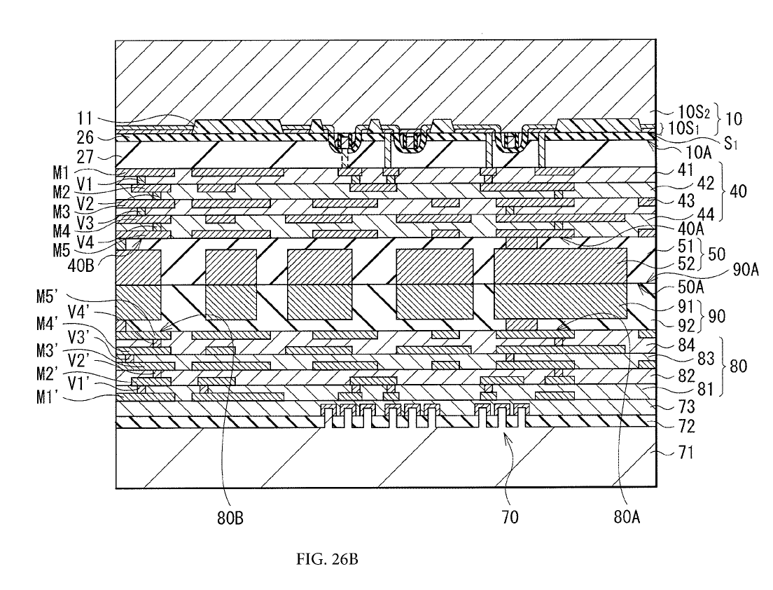

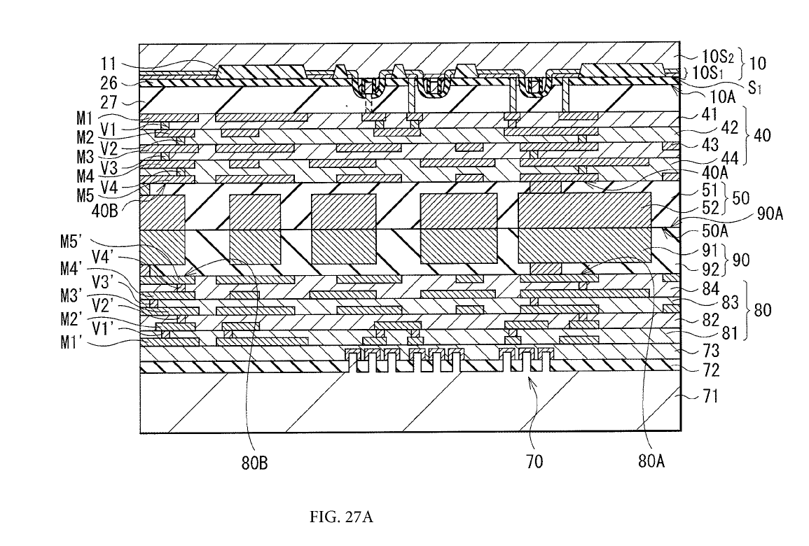

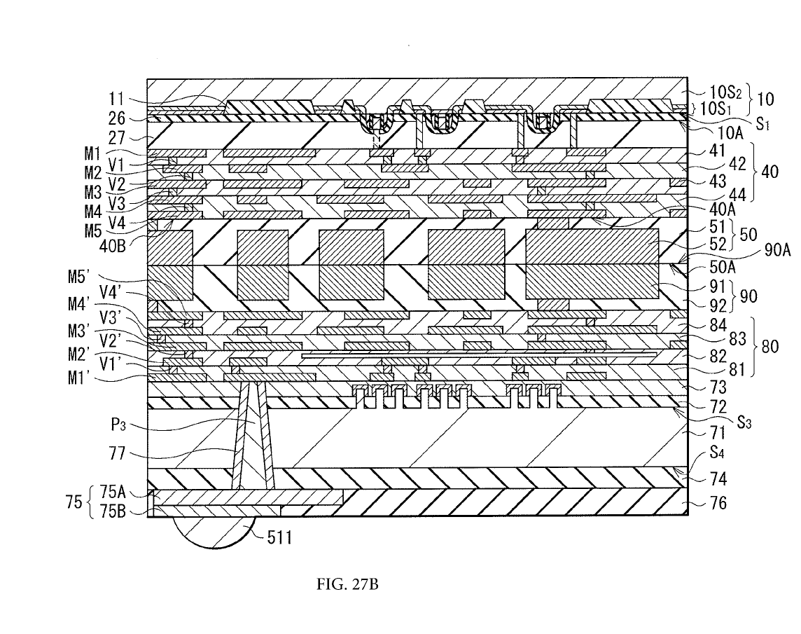

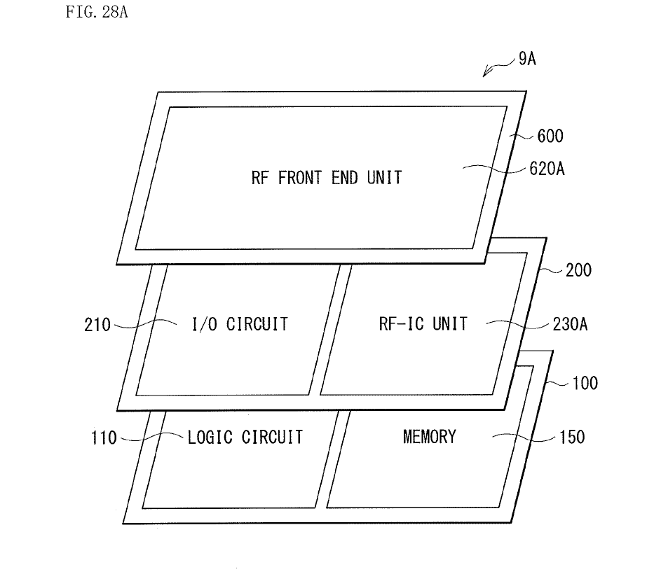

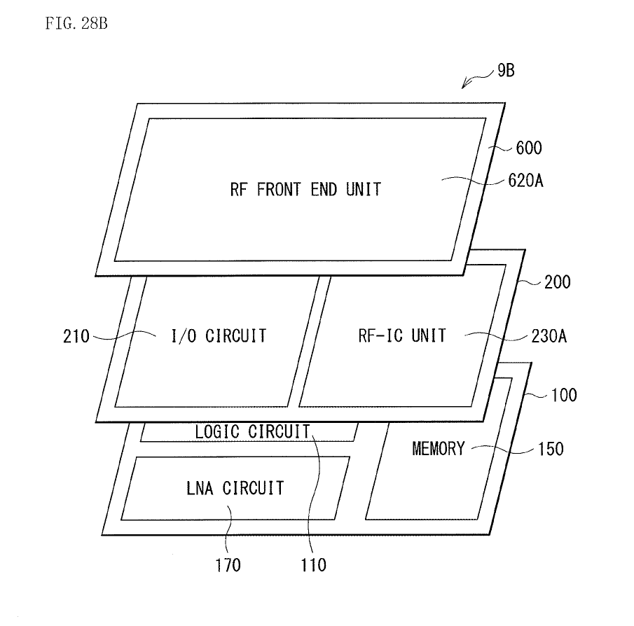

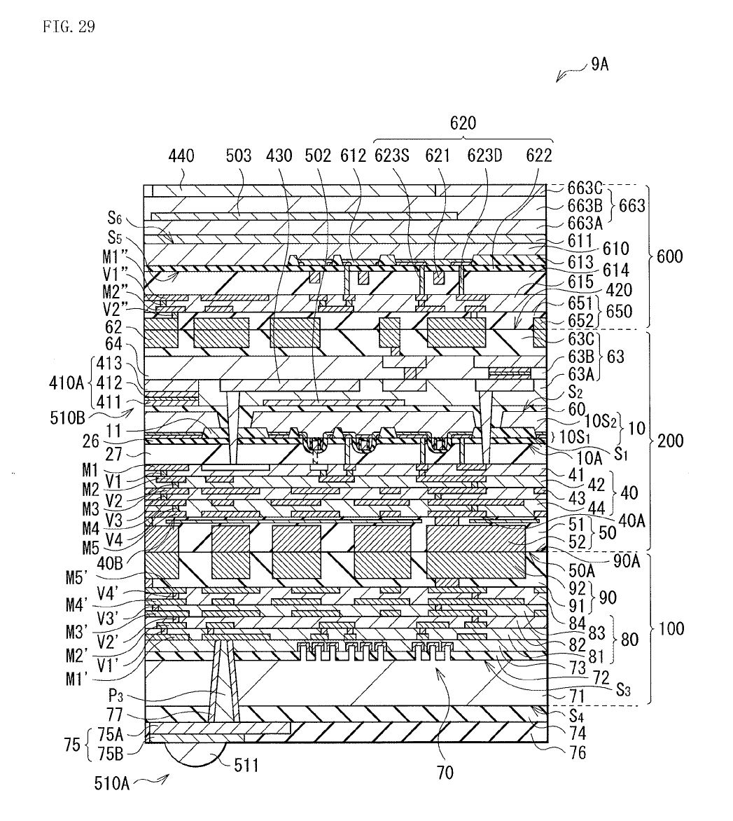

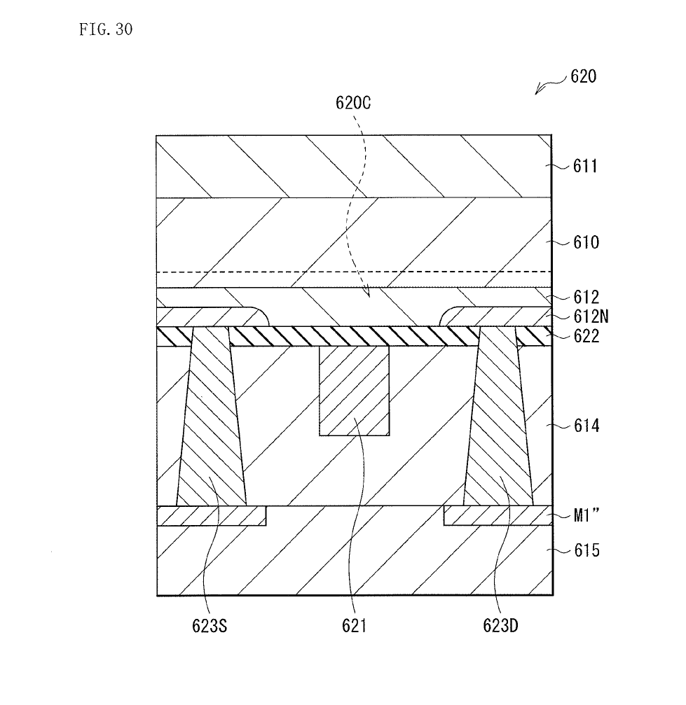

FIG. 20 illustrates a cross-sectional configuration of a semiconductor device (a semiconductor device 7) as a modification example of the foregoing first to fifth embodiments. In the semiconductor device 7, the first substrate 100 and the second substrate 200 are electrically coupled to each other through TSVs H1 and H2, and in the semiconductor devices 2A to 5 described in the foregoing first to fifth embodiments, it is possible to electrically couple the first substrate 100 and the second substrate 200 to each other through the TSVs H1 and H2 as with the present modification example. The TSVs H1 and H2 are formed with, for example, a damascene configuration, and side surfaces of the TSVs H1 and H2 are covered with, for example, an insulating film such as SiO₂. The conductive layer 61 coupled to the back surfaces of the TSVs H1 and H2 is allowed to be used as a power source, for example.

In the present modification example, the first substrate 100 and the second substrate 200 are electrically coupled to each other through the TSVs H1 and H2, which achieves, in addition to the effects in the foregoing embodiments, an effect that it is possible to more easily stack the first substrate 100 and the second substrate 200.

### 7. Sixth Embodiment

FIG. 21A illustrates an example of a schematic configuration of a semiconductor device (a semiconductor device 8) according to a sixth embodiment of the present disclosure. FIG. 21B illustrates a cross-sectional configuration of the semiconductor device 8 illustrated in FIG. 21A. The semiconductor device 8 according to the present embodiment has a configuration in which the transistor 20 configuring various analog circuits is provided on a first surface (the surface S1) of the semiconductor substrate 10 (a core substrate) configuring the second substrate 200, and passive elements (for example, a capacitor 410A, a storage element 420, and an inductor 430) and an antenna 440 are provided on a second surface (the surface S2), as illustrated in FIGS. 21A and 21B. The passive elements and the antenna 440 correspond to specific examples of a “functional element” of the present disclosure. Herein, the first surface (the surface S1) of the semiconductor substrate 10 is a surface on a bonding surface 50A side of the first substrate 100, and the second surface (the surface S2) is a surface facing the first surface.

Moreover, in the semiconductor device 8 according to the present embodiment, a shield structure (for example, shield layers 501A, 501B, etc.) is formed between the transistor 70 provided in the first substrate 100 and the functional element provided in the second substrate 200. Moreover, an extraction electrode (an external coupling electrode 510A) is provided on a second surface S4 facing a first surface S3 (on the bonding surface side of the second substrate 200) of the semiconductor substrate 71 (a core substrate) configuring the first substrate 100.

### (7-1. Configuration of Semiconductor Device)

In the second substrate 200, the multilayer wiring formation unit 40 and the surface wiring formation unit 50 are stacked in this order on the principal surface (the surface S1) of the semiconductor substrate 10, as with the semiconductor device 2 according to the foregoing first embodiment. The Si-planar transistor 20 is provided in proximity to the principal surface 10A of the semiconductor substrate 10. In the present embodiment, the passive elements typified by a capacitor 210A, the storage element 420, and the inductor 430, and the antenna 440 are formed on the back surface (the surface S2) of the semiconductor substrate 10 with the insulating layers 60 and 63 in between.

The capacitor 410A is, for example, a so-called MIM (Metal-Insulator-Metal) capacitor, and includes a metal film 411, an insulating film 412, and a metal film 413 that are stacked in this order on the insulating layer 60. Examples of materials of the metal films 411 and 413 include a Ti base and a Ta base, specifically a metal material including Ti or Ta as a main element. It is to be noted that the metal material may include nitrogen (N) and oxygen (0). Moreover, a metal film that is used as a wiring line and includes copper (Cu), Al, W, etc. may be provided on the metal films 411 and 413 (on a side opposite to the insulating film 412). Examples of a material of the insulating film 412 include metal oxides such as a TaO₂-based metal oxide, a HfO₂-based metal oxide, and a ZO₂-based metal oxide.

It is to be noted that a capacitor 410 actually has, for example, a configuration illustrated in FIG. 22. In other words, the capacitor 410 the capacitor 410 has a configuration in which the metal film 411, the insulating film 412, and the metal film 413 are stacked in this order on the insulating layer 60, and each of the metal film 411 and the metal film 413 is electrically coupled to a back-surface fine contact. Specifically, for example, the metal film 411 is electrically coupled to a contact plug P₅ that penetrates through the insulating layer 63A, the insulating layer 60, the semiconductor substrate 10, and the interlayer insulating films 26 and 27 and electrically couples the metal film M1 and a conductive layer 64 to each other. The metal film 413 is electrically coupled to, for example, a contact plug P₄ that penetrates through, for example, the insulating layer 63A, the insulating layer 60, the semiconductor substrate 10, and the interlayer insulating films 26 and 27 and electrically couples the metal film M1 and the conductive layer 64 to each other. The insulating layer 63A is provided around the insulating film 412 and around the metal films 411 and 413. Moreover, the conductive layer 64 is provided on the metal film 413, and is also embedded in the insulating layer 63A.

The storage element 420 has, for example, a configuration similar to the storage element 30 (a magnetoresistance element) described in the foregoing third embodiment, and includes a conductive layer 421, a storage unit 422 and a conductive layer 423 that are stacked in this order. The conductive layer 421 and the storage unit 422 serve as a lower electrode provided on the conductive layer 64 and the conductive layer 423 serves as an upper electrode. The conductive layer 421 is coupled to the silicide region 25 through the selection line SL and the connection unit 28B, as with the conductive layer 64, the contact plug P₂, and the third embodiment.

An insulating layer 63B is provided around the storage unit 422 and the conductive layers 421 and 423. A conductive layer 65 is provided on the conductive layer 423, and is also embedded in the insulating layer 63B.

The inductor 430 is provided on the insulating layer 63B. The inductor 430 has, for example, a coil shape in which a Cu line is wound, and is embedded in the insulating layer 63C herein.

The antenna 440 is provided on the insulating layer 63C. Although not illustrated, the antenna 440 is electrically coupled to, for example, a transmit-receive switch provided in an RF front end unit (for example, the RF front end unit 220A illustrated in FIG. 2A) as appropriate. The kind of the antenna 440 is not particularly limited, and examples thereof include linear antennas such as a monopole antenna and a dipole antenna and planar antennas such as a microstrip antenna in which a low-K film is sandwiched between metal films. Moreover, the antenna 440 may include, for example, a plurality of antennas 440A, 440B, . . . , as illustrated in FIG. 23. The plurality of antennas 440A, 440B, . . . are provided, and each transmit and receive different data, which makes it possible to achieve speeding up of communication (MIMO technology). An insulating layer 63D is provided around the antenna 440. It is to be noted that the antenna 440 is preferably provided at a position facing, for example, the RF front end unit 220A configuring the above-described analog circuit for communication.

As described above, the transistor is provided on the surface (the surface S1) of the semiconductor substrate 10, and the functional elements of which downsizing is difficult, such as the passive elements including the capacitor 410, the storage element 420, the inductor 430, etc., and the antenna 440 are provided on the back surface (the surface S2) of the semiconductor substrate 10, which makes it possible to reduce the mounting area of an analog circuit substrate (the second substrate 200) that occupies a large area in the semiconductor device.

Moreover, the passive elements and the antenna 440 are formed on a surface different from a surface where the transistor 20 configuring a circuit is provided, which makes it possible to improve flexibility in design and form the passive elements and the antenna 440 with respective suitable film thicknesses, sizes, or materials. Accordingly, it is possible to improve element characteristics of the passive elements and the antenna 440.

Further, for example, strength of a signal to be received by the RF front end unit 220A is dependent on a distance from the antenna. Accordingly, in a case where the antenna is disposed at a far distance, the strength of the signal attenuates; therefore, desired signal processing is not performed in some cases. In particular, this affects higher frequency more significantly. Accordingly, as with the present embodiment, providing the antenna 440 on the back surface (the surface S2) of the semiconductor substrate 10 makes it possible to dispose the antenna 440 and the RF front end unit 220A at a shortest distance from each other and couple the antenna 440 and the RF front end unit 220A to each other.

Furthermore, it is possible to electrically couple a front and a back of the analog circuit corresponding to the passive elements and the antenna 440 mentioned above to each other through a fine back-surface contact. This makes it possible to dispose various circuits mounted in the second substrate 200 in a single circuit level.

Note that in a case where the inductor 430 and the antenna 440 are provided on the back surface (S2) side, there is a possibility that an influence of electromagnetic noise is exerted on the transistor 20 provided in proximity to the principal surface of the semiconductor substrate 10 and the transistor 70 provided in the first substrate 100. Accordingly, in the semiconductor device 9 according to the present embodiment, a shield structure such as a shield layer (for example, shield layers 501A and 501B) to be described below is preferably provided. Providing the shield structure makes it possible to block electromagnetic noise derived from the inductor 430 and the antenna 440.

Examples of a position where the shield layer is formed include a position between the first substrate 100 and the second substrate 200 (for example, between the metal film M4 and the metal film 52 (the shield layers 501A and 501B)), a region (a shield layer 502) facing the inductor 430, and a region (a shield layer 503) facing the antenna 440.

As materials of the shield layers 501A, 501B, 502, and 503, for example, a magnetic material having extremely small magnetic anisotropy and high initial magnetic permeability is preferably used, and examples thereof include a permalloy material. The shield layers 501A, 501B, 502, and 503 may be formed as a solid film, or may be so formed as to have a slit therein as appropriate. Specifically, shapes illustrated in FIGS. 24A to 24C are adopted.

Moreover, a shield pattern structure and formation of a concave-convex structure on a substrate also make it possible to reduce the influence of electromagnetic noise. The concave-convex structure is preferably provided on, for example, the back surface S2 of the semiconductor substrate 10. A concave-convex shape is not particularly limited, but it is preferable to provide, for example, a level difference of 10 nm to 300 nm. It is to be noted that, although not illustrated, each of the shield layers 501A, 501B, 502, and 503 is electrically coupled to one of wiring lines.

Further, in a case where the passive elements, the antenna 440, etc. are formed on the back surface S2 of the semiconductor substrate 10, as with the present embodiment, an electrode extraction port electrically coupled to outside, that is, the external coupling electrode 510A may be provided on the back surface (the surface S4) of the semiconductor substrate 71 configuring the first substrate 100.

The external coupling electrode 510A is a conductive layer 75 provided on the semiconductor substrate 71 with the insulating layer 78 in between. The conductive layer 75 has, for example, a configuration in which a conductive layer 79A formed including Cu and a conductive layer 79B formed including Al are stacked in this order. The conductive layer 75 is electrically coupled to, for example, the metal film M1′ through the contact plug P₃. The insulating layer 79 is provided around the conductive layer 75.

Even in a case where the passive elements, the antenna 440, etc. are formed on the back surface S2 of the semiconductor substrate 10, it is possible to configure the electrode extraction port from anywhere, and to achieve multiple pin connection. Moreover, this makes it easy to form a bump, etc., and advantageously acts on an IR drop in the wiring line.

It is to be noted that it is possible to form the electrode extraction port not only on the back surface S4 of the semiconductor substrate 71 in the first substrate 100 but also on, for example, a side surface of the second substrate by exposing a metal layer serving as an electrode (an external coupling electrode 510B) as with the capacitor 410A.

The contact plugs P₃ and P₄ include, for example, a material mainly including a low-resistance metal such as Cu, W, or aluminum as with the contact plugs P₁ and P₂. Moreover, a barrier metal layer including a simple substance of Ti or Ta or an alloy thereof, etc. may be provided around these low-resistance metals. Circumferences of the contact plugs P₃ and P₄ are covered with an insulating layer (for example, an insulating layer 76), and the contact plug P₃ and P₄ are electrically separated from surroundings thereof.

Materials of the insulating layers 63A, 63B, 64C, and 63D configuring the insulating layer 63 include SiO₂, a low-K (low dielectric constant) film, and a high-K (high dielectric constant) film; however, the low-K (low dielectric constant) film is desirable. Materials of the insulating layers 78, 78A, and 79 include SiO₂, SiN, SiON, and a low-K (low dielectric constant). In particular, the insulating layer 78 is preferably formed using SiO₂, and the insulating layer 79 may be formed using any of the materials mentioned above.

### (7-2. Manufacturing Method)

It is possible to manufacture the semiconductor device 9 according to the present embodiment in accordance with a flow chart illustrated in FIG. 25, for example. The manufacturing procedure is described below with reference to FIGS. 26A to 27B.

First, the first substrate 100 (A) and the second substrate 200 (B) are manufactured as illustrated in FIG. 26A (steps S101a and S101b). Next, for example, the second substrate 200 is turned upside down, and the bonding surface 50A of the second substrate 200 is bonded to a bonding surface 90A of the first substrate 100 (step S102). Subsequently, a semiconductor substrate 10S? of the second substrate 200 is thinned, as illustrated in FIG. 27A (step S103). At this time, the semiconductor substrate 71 of the first substrate 100 may be also thinned to, for example, a thickness of several μm. In particular, in a case where, as with a modification example 3 to be described later, the first substrate 100 is stacked on the second substrate 200, and the functional element such as the antenna 440 and the non-volatile element such as the storage element 420 are provided on the back surface of the first substrate 100, the semiconductor substrate 71 of the first substrate 100 is preferably thinned. Subsequently, the external coupling electrode 510A is formed on the back surface S4 of the first substrate 100, as illustrated in FIG. 27B (step S104). Lastly, the insulating layer 60, the capacitor 410A, the storage element 420, the inductor 430, the antenna 440, etc. are sequentially formed in order on the thinned semiconductor substrate 105₂ (step S105). The semiconductor device 9 illustrated in FIG. 21 is completed.

### (7-3. Workings and Effects)

As described above, in the present embodiment, the passive elements such as the capacitor 410, the storage element 420, and the inductor 430 of which downsizing is difficult are provided on the back surface S2 of the semiconductor substrate 10 configuring the second substrate 200. This achieves, in addition to the effects in the foregoing first embodiment, an effect that it is possible to reduce the mounting area of the second substrate 200 where the analog circuit is provided without largely increasing the number of processes. Moreover, the antenna 440 is provided on the back surface S2 of the semiconductor substrate 10, which achieves an effect that it is possible to reduce a distance from the circuit for communication to suppress attenuation of the signal, thereby improving reliability in signal processing.

### 8. Modification Example 2

FIG. 28A is a block diagram illustrating an example of a schematic configuration of a semiconductor device (a semiconductor device 9A) as a modification example of the semiconductor device (for example, the semiconductor device 2A) according to the foregoing first embodiment. FIG. 29 illustrates an example of a specific cross-sectional configuration of the semiconductor device 9A.

The semiconductor device 2A including the platform for communication applicable to various frequency bands from a close distance to a far distance generally uses a silicon (Si) substrate as a core substrate, but in some cases, a compound-based semiconductor substrate is partially used. Of the I/O circuit 210, the RF front end unit 220A, and the RF-IC unit 230A mounted in the second substrate 200 in the semiconductor device 2A, in some cases, for example, the I/O circuit 210 and the RF-IC unit 230A are provided in a Si substrate, and the RF front end unit 220A is provided in, for example, a gallium nitride (GaN) substrate. In such a case, the RF front end unit 220A configured using a substrate including a different material that is the GaN substrate herein may be stacked as a third substrate 600 on, for example, the second substrate 200 including the PO circuit 210 and the RF-IC unit 230A, as illustrated in FIG. 29. The present modification example has a configuration in which a GaN substrate is used for the semiconductor substrate 10 in the third substrate 600.

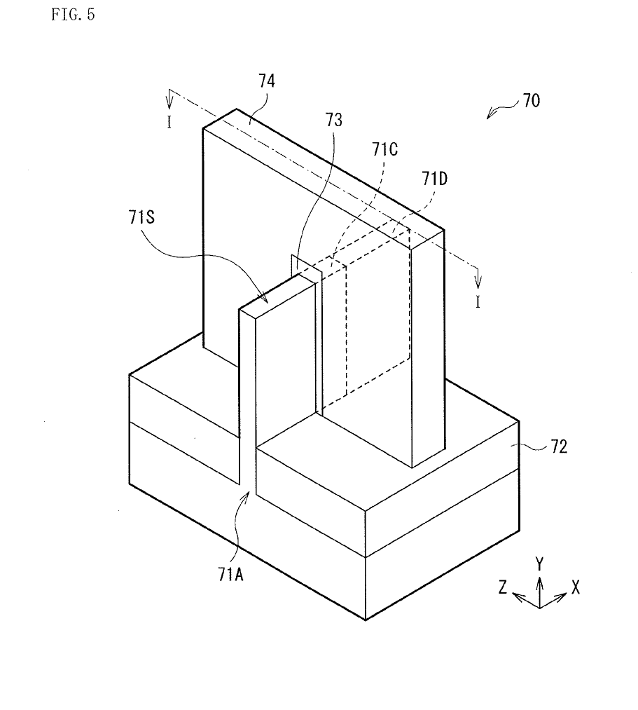

In the semiconductor device 9A, the first substrate 100 and the second substrate 200 are bonded to each other with the surface wiring formation units 50 and 90 in between, as with the foregoing semiconductor device 2. In the first substrate 100, for example, the fin-FET transistor 70 as illustrated in FIG. 5 is provided on the principal surface (the surface S3) of the semiconductor substrate 71, and the external coupling electrode 510A is provided on the back surface (the surface S4) of the semiconductor substrate 71. In the second substrate 200, the Si-planar transistor 20 is provided in proximity to the principal surface (the surface S1) 10A of the semiconductor substrate 10, as with the foregoing semiconductor device 8. For example, the capacitor 210A, the storage element 420, and the inductor 430 are formed on the back surface (the surface S2) of the semiconductor substrate 10 with the insulating layers 60 and 63 in between. The metal film 62 configuring the surface wiring formation unit is formed on the capacitor 410A the storage element 420, and the inductor 430 with the insulating layer 63 (63A to 63C) in between.

In the third substrate 600, a plurality of transistors 620 are provided on the principal surface (the surface S5) of the GaN substrate 610. FIG. 30 illustrates a cross-sectional configuration of the transistor 620. The transistor 620 is, for example, a high electron mobility transistor (HEMT). The HEMT is a transistor that controls two-dimensional electron gas (a channel region 620C) formed at a heterojunction interface between different kinds of semiconductors by an electrical field effect. For example, an AlGaN layer 612 (or an AlInN layer) is provided on the GaN substrate 610, which forms an AlGaN/GaN heterostructure. A gate electrode 621 is provided on the AlGaN layer 612 with a gate insulating film 622 in between. Moreover, a source electrode 623S and a drain electrode 623D are provided on the AlGaN layer 612 with the gate electrode 621 in between. An n-type region 612 is provided in the AlGaN layer in contact with each of the source electrode 623S and the drain electrode 623D. An element separation layer 613 is provided between respective transistors 620. An interlayer insulating film 614 is formed around the gate electrode 621, the source electrode 6235, and the drain electrode 623D, and a multilayer wiring formation unit having a configuration in which a metal film M1″ and a metal film M2″ are stacked in order from a side close to the transistor 620 is provided on the interlayer insulating film 614. Moreover, the metal film M1″ and the metal film M2″ are embedded in a interlayer insulating film 615, and the metal film M1″ and the metal film M2″ are coupled to each other through a via V1″ that penetrates through the interlayer insulating film 615. A surface wiring formation unit 650 that is surface-bonded to the metal film 62 of the second substrate 200 is provided on the multilayer wiring formation unit. In the surface wiring formation unit 650, for example, a metal film 652 formed including copper (Cu) is embedded in a surface of an insulating film 651, and the metal film 652 is coupled to the metal film M2″ through a via V2″ that penetrates through the insulating film 651.

A Si substrate 611 as a base substrate is provided on a back surface (a surface S6) of the GaN substrate 610. The shield layer 503 is provided on the Si substrate 611 with an insulating layer 663A in between, and the antenna 440 is provided on the shield layer 503 with an insulating layer 663B in between. An insulating layer 663C is provided around the antenna 440. It is to be noted that the Si substrate 611 may be thinned or removed by polishing in a procedure of manufacturing the semiconductor device 9A to directly stack the insulating layer 663A on the GaN substrate 610. Thinning or removing the Si substrate 611 reduces parasitic capacity of the Si substrate 611 and improve responsivity of various circuits mounted in the third substrate 600.

In the present modification example, in addition to the effects in the foregoing first embodiment, in a case where a compound semiconductor substrate, for example, a GaN substrate is used as a substrate, and, for example, an amplifier circuit including an amplifier is provided in the GaN substrate, distortion is suppressed, as compared with the Si substrate, which makes it possible to widen an operation bandwidth. Moreover, for example, in a case where a switch element is provided, responsivity with respect to high frequency is improved.

It is to be noted that FIG. 29 illustrates an example in which the capacitor 210A, the storage element 420, and the inductor 430 are provided on the back surface S2 of the second substrate 200; however, the present modification example is not limited thereto, and the capacitor 210A, the storage element 420, and the inductor 430 are provided together with the antenna 440 on the back surface S6 of the third substrate 600.

Moreover, although not illustrated, the antenna 440 is electrically coupled to the transmit-receive switch provided in, for example, an RF front end unit (for example, the RE front end unit 220A illustrated in FIG. 22A) as appropriate, as with the sixth embodiment. The shield layers 502 and 503 are also electrically coupled to one of wiring

Further, for example, in a case where a circuit (for example, a LNA circuit or a transmit-receive mixer) mounted in the RF-IC unit 230A includes, for example, a transistor having a low driving voltages such as a fin-field effect transistor as described above, the LNA circuit 170 may be provided in the first substrate 100 in a manner similar to FIG. 2C, as with a semiconductor device 9B illustrated in FIG. 28B. Furthermore, for example, a circuit (for example, an LNA circuit or a transmit-receive mixer) mounted in the RF-IC unit 230A or a circuit (for example, a transmit-receive switch or a power amplifier) mounted in the RF front end unit 220A includes, for example, a HEMT, the circuit may be provided in the third substrate 600.

### 9. Modification Example 3

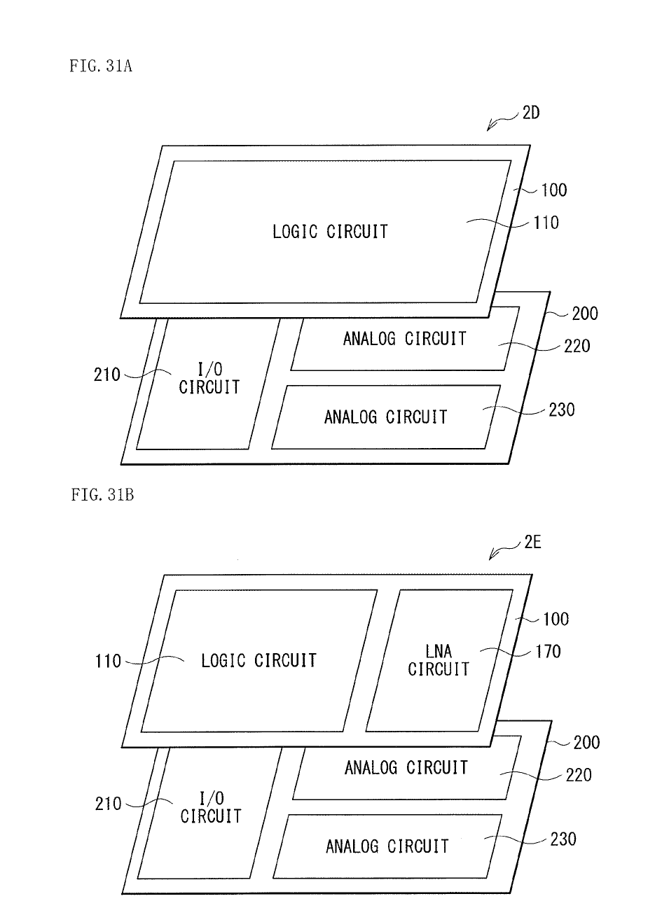

FIG. 31A is a block diagram illustrating an example of a schematic configuration of a semiconductor device (a semiconductor device 2D) as a modification example of the foregoing first to sixth embodiments and the foregoing modification examples 1 and 2. In the foregoing embodiments, etc., description has been given of the semiconductor devices 2A to 9 in which the second substrate 200 including the transistor to be driven at the highest voltage is mounted on the first substrate 100 including the transistor to be driven at the lowest voltage; however, the stacking order of the first substrate 100 and the second substrate 200 may be reversed. In the present modification example, description is given with reference to the stacked body illustrated in FIG. 1 as an example, and, for example, a configuration in which the first substrate 100 including the logic circuit 110 is stacked on the second substrate 200 including the I/O circuit 210 and the analog circuits 220 and 230 may be adopted.

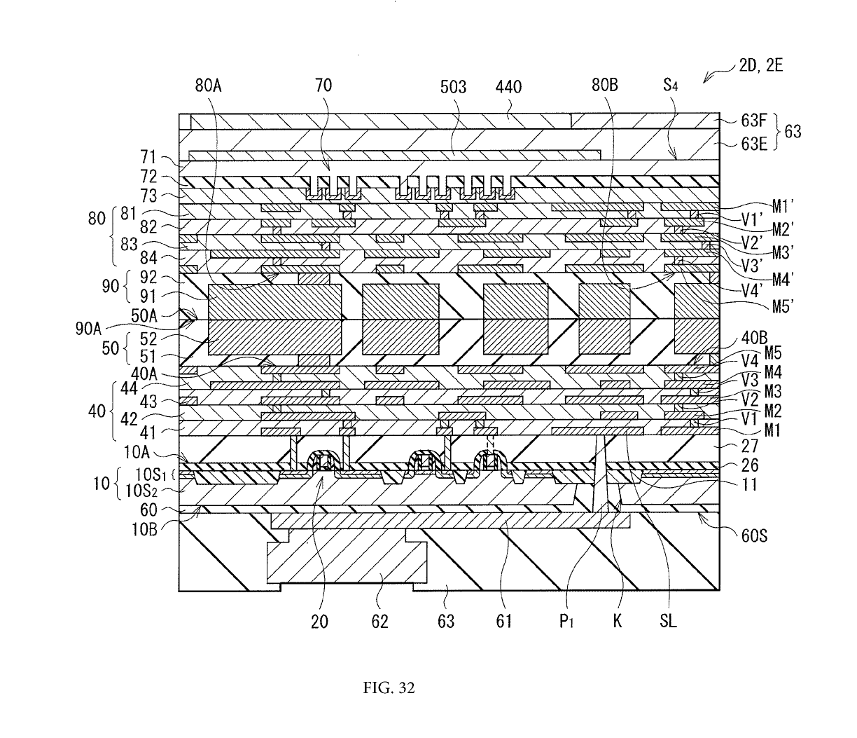

FIG. 32 illustrates an example of a specific cross-sectional configuration of the semiconductor device 2D or a semiconductor device 2E. In a case where the first substrate 100 is provided on the second substrate 200, the functional element, the non-volatile elements, etc. mentioned above may be provided on the back surface S₄ of the semiconductor substrate 71 of the first substrate 100. FIG. 32 illustrates an example in which the antenna 440 is provided as an example of the functional element on the back surface S₄ of the first substrate 100. It is to be noted that in a case where the functional element is provided on the back surface S₄ of the semiconductor substrate 71, a shield structure (for example, the shield layer 503) is preferably provided as appropriate, as illustrated in FIG. 32. In FIG. 32, the shield layer 503 provided on the back surface S₄ of the semiconductor substrate 71 is embedded in an insulating layer 63E, and the antenna 440 is provided on the insulating layer 63E. An insulating layer 63F is provided around the antenna 440. Materials of the insulating layer 63E and the insulating layer 63F include SiO₂, a low-K (low dielectric constant) film, a high-K (high dielectric constant) film, etc., as with the insulating layer 63 according to the foregoing sixth embodiment, but the low-K (low dielectric constant) film is desirable.

It is to be noted that for example, in a case where a circuit (for example, an LNA circuit and a transmit-receive mixer) mounted in the RF-IC unit 230A includes, for example, a transistor having a low driving voltage such as a fin field effect transistor as with the first embodiment and the modification example 2, the LNA circuit 170 may be provided in the first substrate 100 as with the semiconductor device 2E illustrated in FIG. 31B. Moreover, for example, in a case where a circuit (for example, an LNA circuit and a transmit-receive mixer) mounted in the RF-IC unit 230A or a circuit (for example, a transmit-receive switch and a power amplifier) mounted in the RF front end unit 220A includes, for example, an HEMT, the circuit may be provided in the third substrate 600.

It is to be noted that in a case where, for example, the LNA circuit 170 is mounted in the first substrate 100, and, for example, the power amplifier is mounted in the third substrate 600, the LNA circuit 170 and the power amplifier are preferably disposed at positions as close as possible to each other in consideration of data exchange. In such a case, as with the present modification example, a configuration in which the first substrate is disposed on an upper side and the second substrate 200 is disposed on a lower side makes it possible to dispose the LNA circuit 170 and the power amplifier at positions close to each other.

Although the present disclosure has been described above by referring to the first to sixth embodiments and the modification examples 1 to 3, the present disclosure is not limited thereto, and may be modified in a variety of ways. For example, in the foregoing embodiments, etc., the semiconductor devices 2A to 7 in which the logic circuit is mounted in one substrate (the first substrate 100) has been described; however, the present disclosure is not limited thereto, and the logic circuit may be mounted on a plurality of substrates. Moreover, a circuit including a transistor having the lowest driving voltage may be formed in a substrate other than the first substrate 100. At this occasion, the other substrate does not include a transistor to be driven at the highest voltage of a plurality of transistors configuring any of the semiconductor devices 2A to 7.

Moreover, in the foregoing first to fourth embodiments, the semiconductor devices 2A to 5 including two layers, i.e., the first substrate 100 and the second substrate 200 are exemplified; however, a semiconductor device having a three-layer configuration as with the fifth embodiment may be adopted, and further a semiconductor device having a configuration in which a plurality of layers are stacked may be adopted.

Further, the configurations of the transistors 20 and 70 and the storage element 30 have been described in detail in the foregoing embodiments, etc.; however, it is not necessary to provide all of the components, or any other components may be further included.

Furthermore, the semiconductor device of the present disclosure may further include, for example, a circuit having a power source function and a circuit having an audio function in addition to the circuits described in the foregoing first to sixth embodiments, and these circuits are mounted in, for example, the second substrate 200.

It is to be noted that the effects described herein are merely exemplified and non-limiting, and effects achieved by the technology may be effects other than those described herein. Moreover, the present technology may have the following configurations.
(1)

A stacked body, including:

a plurality of transistors;

a first substrate; and

a second substrate that is stacked with the first substrate and is electrically coupled to the first substrate,

wherein a first transistor to be driven at a first driving voltage being a lowest voltage of the plurality of transistors is provided only in the first substrate of the first substrate and the second substrate to form a first circuit.
(2)

The stacked body according to (1), in which a second circuit including a second transistor to be driven at a second driving voltage higher than the first driving voltage of the plurality of transistors is formed in the second substrate.
(3)

The stacked body according to (2), in which the first circuit further includes a third transistor to be driven at a third driving voltage higher than the first driving voltage and lower than the second driving voltage.
(4)

The stacked body according to (2) or (3), in which

each of the first transistor and the second transistor includes a gate electrode, a pair of source-drain electrodes, a semiconductor film that forms a channel, and a gate insulating film provided between the gate electrode and the semiconductor film, and a thickness of the gate insulating film in the second transistor is thicker than a thickness of the gate insulating film in the first transistor.
(5)

The stacked body according to any one of (1) to (4), in which a semiconductor layer of the first transistor includes one of silicon (Si), germanium (Ge), a compound semiconductor, and graphene.
(6)

The stacked body according to (5), in which the compound semiconductor is a group MN semiconductor or a group II-VI semiconductor.
(7)

The stacked body according to any one of (1) to (6), in which the first transistor is one or more kinds of a transistor using a high dielectric constant film/metal gate (high-K/metal gate) technology, a fully-depleted transistor, and a T-FET.
(8)

The stacked body according to (7), in which the fully-depleted transistor is a fin-FET, a tri-gate transistor, a nano-wire transistor, and an FD-SOI transistor.
(9)

The stacked body according to any one of (2) to (8), in which the first circuit is a logic circuit, and the second circuit is an analog circuit.
(10)

The stacked body according to any one of (1) to (9), in which the first substrate and the second substrate are electrically coupled to each other through surface-bonding or a through electrode.
(11)

The stacked body according to any one of (1) to (10), in which an input-output circuit and a pad electrode that is coupled to outside are mounted in the second substrate.
(12)

The stacked body according to any one of (1) to (11), in which one or more circuits having a communication function that allows for transmission and reception in a plurality of frequency bands are mounted in the second substrate.
(13)

The stacked body according to (12), in which the circuit having a communication function that allows for transmission and reception in a plurality of frequency bands includes an RF front end unit including a transmit-receive switch and a power amplifier and an RF-IC unit including a low noise amplifier and a transmit-receive mixer.
(14)

The stacked body according to (13), in which in a case where the RF front end unit and the RF-IC unit include a third circuit including the third transistor, the third circuit is provided in the first substrate.
(15)

The stacked body according to any one of (1) to (14), in which at least a circuit having an image sensor function, a circuit having a temperature sensor function, a circuit having a gravity sensor function, and a circuit having a position sensor function are mounted in the second substrate.
(16)

The stacked body according to any one of (1) to (15), in which a circuit including a non-volatile element that has a memory function is mounted in the second substrate.
(17)

The stacked body according to any one of (1) to (16), in which a circuit of one or more kinds of interface standards is mounted the second substrate.
(18)

The stacked body according to (17), in which the interface standards are an MIPI, the MIPI includes a digital controller and a PHY unit, and the digital controller and the PHY unit are respectively mounted in the first substrate and the second substrate.
(19)

The stacked body according to (18), in which the PHY unit includes the second circuit and a third circuit including the third transistor, and the third circuit is provided in the first substrate.
(20)

The stacked body according to any one of (1) to (20), in which a logic circuit, an analog circuit, and a pixel unit are included, the analog circuit, the logic circuit, and the pixel unit are respectively mounted in the second substrate, the first substrate, and the third substrate.
(21)

The stacked body according to any one of (2) to (20), in which the second substrate includes a core substrate, and the second transistor is formed on a first surface of the core substrate, and a functional element is formed on a second surface facing the first surface.
(22)

The stacked body according to (21), in which the first surface of the second substrate faces the first substrate.
(23)

The stacked body according to (21) or (22), in which the functional element is one or more kinds of an inductor, a capacitor, a non-volatile element, and an antenna.
(24)

The stacked body according to any one of (21) to (23), in which a shield structure is included between the first substrate and the functional element.
(25)

The stacked body according to (24), in which the shield structure is a shield layer including a permalloy material.
(26)

The stacked body according to (25), in which the shield layer is provided between the first transistor provided in the first substrate and the second transistor provided in the second substrate.
(27)

The stacked body according to (25) or (26), in which the shield layer has a slit.
(28)

The stacked body according to any one of (25) to (27), in which the shield structure is a concave-convex structure provided on the second surface of the core substrate of the second substrate.
(29)

The stacked body according to any one of (21) to (28), in which

the second substrate includes an insulating film between the core substrate and the functional element, and

the insulating film is formed including an insulating material having a lower K value than silicon oxide.
(30)

The stacked body according to any one of (23) to (27), in which the antenna is provided at a position facing the RF front end unit.
(31)

The stacked body according to any one of (23) to (30), in which the second substrate includes a plurality of the antennas of which one or both of frequency bands and communication standards are different.
(32)

The stacked body according to any one of (23) to (31), in which the antenna is one or more kinds of a monopole antenna, a dipole antenna, and a microstrip
(33)

The stacked body according to any one of (23) to (32), in which the capacitor includes a pair of electrodes, and each of the pair of electrodes is electrically coupled to corresponding one of different back-surface fine contacts.
(34)

The stacked body according to any one of (23) to (33), in which the capacitor is formed including a tantalum oxide (TaO₂) base, a hafnium oxide (HfO₂) base, or a zirconium oxide (ZrO₂) base.
(35)

The stacked body according to any one of (1) to (34), in which the second substrate is stacked on the first substrate.
(36)

The stacked body according to any one of (1) to (34), in which the first substrate is stacked on the second substrate.
(37)

The stacked body according to any one of (21) to (36), in which the first substrate includes a core substrate, and the first transistor is included on a first surface of the core substrate, and one or more kinds of the functional element and the non-volatile element are formed on a second surface facing the first surface.
(38)

The stacked body according to any one of (1) to (37), in which a circuit for I/O coupling is mounted in the second substrate.
(39)

The stacked body according to any one of (1) to (38), in which a programmable circuit or an element is mounted in the first substrate.
(40)

The stacked body according to (39), in which the programmable circuit includes a FPGA (field-programmable gate array) and a CPU (central processing unit).
(41)

The stacked body according to any one of (1) to (21), in which an extraction electrode is provided on a surface opposite to a surface facing the second substrate of the first substrate.
(42)

The stacked body according to any one of (21) to (41), in which a compound semiconductor substrate is used as the core substrate in the second substrate.
(43)

The stacked body according to any one of (1) to (42), in which a fourth substrate including a compound semiconductor substrate as a core substrate is included, and the fourth substrate is electrically coupled to one or both of the first substrate and the second substrate.
(44)

The stacked body according to (43), in which the compound semiconductor substrate is in contact with an insulating layer.
(45)

The stacked body according to (43) or (44), in which a low noise amplifier is mounted in the first substrate, and a power amplifier is mounted in the fourth substrate.

The present application is based on and claims priority from Japanese Patent Application No. 2015-172264 filed in the Japan Patent Office on Sep. 1, 2015 and Japanese Patent Application No. 2016-042653 filed in the Japan Patent Office on Mar. 4, 2016, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A stacked body, comprising:
a plurality of transistors;
a first substrate; and
a second substrate that is stacked with the first substrate and is electrically coupled to the first substrate,
wherein a first transistor to be driven at a first driving voltage being a lowest voltage of the plurality of transistors is provided only in the first substrate of the first substrate and the second substrate to form a first circuit.

2. The stacked body according to claim 1, wherein a second circuit including a second transistor to be driven at a second driving voltage higher than the first driving voltage of the plurality of transistors is formed in the second substrate.

3. The stacked body according to claim 2, wherein the first circuit further includes a third transistor to be driven at a third driving voltage higher than the first driving voltage and lower than the second driving voltage.

4. The stacked body according to claim 2, wherein
each of the first transistor and the second transistor includes a gate electrode, a pair of source-drain electrodes, a semiconductor film that forms a channel, and a gate insulating film provided between the gate electrode and the semiconductor film, and
a thickness of the gate insulating film in the second transistor is thicker than a thickness of the gate insulating film in the first transistor.

5. The stacked body according to claim 1, wherein a semiconductor layer of the first transistor includes one of silicon (Si), germanium (Ge), a compound semiconductor, and graphene.

6. The stacked body according to claim 1, wherein the first transistor is one or more kinds of a transistor using a high dielectric constant film/metal gate (high-K/metal gate) technology, a fully-depleted transistor, and a T-FET.

7. The stacked body according to claim 2, wherein the first circuit is a logic circuit, and the second circuit is an analog circuit.

8. The stacked body according to claim 1, wherein the first substrate and the second substrate are electrically coupled to each other through surface-bonding or a through electrode.

9. The stacked body according to claim 1, wherein one or more circuits having a communication function that allows for transmission and reception in a plurality of frequency bands are mounted in the second substrate.

10. The stacked body according to claim 9, wherein the circuit having a communication function that allows for transmission and reception in a plurality of frequency bands includes an RF front end unit including a transmit-receive switch and a power amplifier and an RF-IC unit including a low noise amplifier and a transmit-receive mixer.

11. The stacked body according to claim 10, wherein in a case where the RF front end unit and the RF-IC unit include a third circuit including a third transistor having a driving voltage lower than the driving voltage of the second transistor provided in the second substrate and higher than the driving voltage of the first transistor, the third circuit is provided in the first substrate.

12. The stacked body according to claim 1, wherein at least a circuit having an image sensor function, a circuit having a temperature sensor function, a circuit having a gravity sensor function, and a circuit having a position sensor function are mounted in the second substrate.

13. The stacked body according to claim 1, wherein
a circuit of one or more kinds of interface standards is mounted in the second substrate, and
the interface standards are an MIPI, the MIPI includes a digital controller and a PHY unit, and the digital controller and the PHY unit are respectively mounted in the first substrate and the second substrate.

14. The staked body according to claim 1, wherein a logic circuit, an analog circuit, and a pixel unit are included, the analog circuit, the logic circuit, and the pixel unit are respectively mounted in the second substrate, the first substrate, and the third substrate.

15. The stacked body according to claim 2, wherein the second substrate includes a core substrate, the second transistor is formed on a first surface of the core substrate, a functional element is formed on a second surface facing the first surface, and the functional element is one or more kinds of an inductor, a capacitor, a non-volatile element, and an antenna.

16. The stacked body according to claim 15, wherein a shield structure is included between the first substrate and the functional element, and the shield structure is a concave-convex structure provided on the second surface of the core substrate of the second substrate, or a shield layer including a magnetic material.

17. The stacked body according to claim 15, wherein
the second substrate includes an RF front end unit including a transmit-receive switch and a power amplifier, and
the antenna is provided at a position facing the RF front end unit.

18. The stacked body according to claim 15, wherein the first substrate includes a core substrate, and the first transistor is included on a first surface of the core substrate, and one or more kinds of the functional element and the non-volatile element are formed on a second surface facing the first surface.

19. The stacked body according to claim 1, wherein a programmable circuit or an element is mounted in the first substrate, and the programmable circuit includes a FPGA (field-programmable gate array) and a CPU (central processing unit).

20. The stacked body according to claim 15, wherein an extraction electrode is provided on a surface opposite to a surface facing the second substrate of the first substrate.

21. The stacked body according to claim 15, wherein a compound semiconductor substrate is used as the core substrate in one or both of the second substrate and a fourth substrate.

22. The stacked body according to claim 21, wherein the compound semiconductor substrate is in contact with an insulating layer.

23. The stacked body according to claim 21, wherein a low noise amplifier is mounted in the first substrate, and a power amplifier is mounted in the fourth substrate.
